(19) United States
(12) Patent Application Publication
(10) Pub. No.: US 2023/0109185 A1
(43) Pub. Date: Apr. 6, 2023

(54) An organic light emitting device

(71) Applicant: Cambridge Enterprise Limited, Cambridge (GB)

(72) Inventors: Richard FRIEND, Cambridge (GB); Emrys EVANS, Cambridge (GB); Feng LI, Cambridge (GB)

(21) Appl. No.: 17/784,102

(22) PCT Filed: Dec. 9, 2020
(86) PCT No.: PCT/EP2020/085388

§ 371 Date: Jun. 9, 2022

(30) Foreign Application Priority Data
Dec. 10, 2019 (GB) 1918121.3

(51) Int. Cl. H01L 51/50; H01L 51/00

(52) U.S. Cl. CPC H01L 51/5016; H01L 51/5004; H01L 51/0071; H01L 51/008; H01L 51/0072; H01L 51/0064; H01L 51/0059; H01L 2251/552

(57) ABSTRACT

An organic light emitting device, comprising an anode; a cathode; and an emissive layer between the anode and the cathode, wherein the emissive layer comprises a first material which is an organic semiconductor compound and a second material which is a different organic semiconductor compound that has a spin doublet ground state; and wherein a lowest spin singlet excitation energy of the first material and a lowest spin triplet excitation energy of the first material are greater than a lowest spin doublet excitation energy of the second material; a method of fabricating an organic light emitting device, comprising: forming an emissive layer between an anode and a cathode, wherein the emissive layer comprises a first material which is an organic semiconductor compound and a second material which is a different organic semiconductor compound that has a spin doublet ground state; and wherein a lowest spin singlet excitation energy of the first material and a lowest spin triplet excitation energy of the first material are greater than a lowest spin doublet excitation energy of the second material; and a method of operating the device by applying a voltage across the device, such that spin singlet excited states and spin triplet excited states are formed for the first material, wherein energy is transferred from spin singlet excited states in the first material and spin triplet excited states in the first material to form spin doublet excited states in the second material, wherein the second material emits fluorescent light when transitioning from a spin doublet excited state to a ground state.

### FIELD

The present invention relates to an organic light emitting device, a method of operating an organic light emitting device and a method for fabricating an organic light emitting device.

### BACKGROUND

Organic light-emitting diodes (OLEDs) find widespread use in various applications, including in display and lighting technologies for example. OLEDs comprise organic molecules which emit light following electrical charge injection. Various OLED devices in which the organic molecules are closed-shell molecules are known. For closed-shell molecules with a singlet spin 0 ground state, electrical excitation leads to the formation of 25% singlet and 75% triplet excitons. A fluorescent device using emission from singlet excitons is thus believed to have a maximum possible electroluminescence efficiency of 25%. Thermally activated delayed fluorescence (TADF) is a process in which delayed fluorescence from an excited spin singlet state follows reverse intersystem crossing from the spin triplet excited state to the spin singlet excited state. Improved electroluminescence efficiency may be obtained for devices using TADF materials. However, delayed fluorescence is often associated with lifetimes of microseconds and longer.

### BRIEF DESCRIPTION OF FIGURES

Systems and methods in accordance with non-limiting embodiments will now be described with reference to the accompanying figures in which:

FIG. 1 shows a schematic illustration of an organic light emitting device in accordance with an embodiment;

FIG. 2 shows a schematic illustration of the light emission mechanism occurring in the emissive layer of an organic light emitting device in accordance with an embodiment when a voltage is applied;

FIG. 3(a) shows a schematic illustration of a Dexter energy transfer process; FIG. 3(b) shows a schematic illustration of a Förster energy transfer process;

FIG. 4 shows experimental data of transient photoluminescence measurements for various materials;

FIG. 5 shows experimental data in which the external quantum efficiency (EQE) is shown on the y-axis, against current density on the x-axis, for various devices;

FIG. 6 shows experimental data, in which the diode characteristic of the current density against voltage is plotted for the device of Example 1 and the device of Comparative Example 1;

FIG. 7 shows normalised electroluminescence (EL) profiles for the device according to Example 1;

FIG. 8 shows experimental data in which the external quantum efficiency (EQE) is shown on the y-axis, against current density on the x-axis, for the device of Example 2;

FIG. 9 shows the current density against voltage diode characteristic of the device according to Example 2;

FIG. 10 shows normalised electroluminescence (EL) profiles for the device according to Example 2;

FIG. 11 shows experimental data in which the external quantum efficiency (EQE) is shown on the y-axis, against current density on the x-axis, for the device of Example 3;

FIG. 12 shows the current density against voltage diode characteristic of the device according to Example 3;

FIG. 13 shows normalised electroluminescence (EL) profiles for the device according to Example 3;

FIG. 14 shows experimental data in which the external quantum efficiency (EQE) is shown on the y-axis, against current density on the x-axis, for the device of Example 4;

FIG. 15 shows the current density against voltage diode characteristic of the device according to Example 4;

FIG. 16 normalised electroluminescence (EL) profiles for the device according to Example 4;

FIG. 17 shows experimental data in which the external quantum efficiency (EQE) is shown on the y-axis, against current density on the x-axis, for the device of Example 5;

FIG. 18 shows the current density against voltage diode characteristic of the device according to Example 5;

FIG. 19 shows normalised electroluminescence (EL) profiles for the device according to Example 5.

FIG. 20 shows the current density against voltage diode characteristic of the device according to Example 6;

FIG. 21 shows experimental data in which the external quantum efficiency (EQE) is shown on the y-axis, against current density on the x-axis, for the device of Example 6;

FIG. 22 shows normalised electroluminescence (EL) profiles for the device according to Example 6;

FIG. 23 shows the current density against voltage diode characteristic of the device according to Example 7;

FIG. 24 shows experimental data in which the external quantum efficiency (EQE) is shown on the y-axis, against current density on the x-axis, for the device of Example 7;

FIG. 25 shows normalised electroluminescence (EL) profiles for the device according to Example 7;

FIG. 26 shows the current density against voltage diode characteristic of the device according to Example 8;

FIG. 27 shows experimental data in which the external quantum efficiency (EQE) is shown on the y-axis, against current density on the x-axis, for the device of Example 8;

FIG. 28 shows normalised electroluminescence (EL) profiles for the device according to Example 8.

### DETAILED DESCRIPTION

According to an embodiment, there is provided an organic light emitting device, comprising:
an anode;
a cathode; and
an emissive layer between the anode and the cathode, wherein the emissive layer comprises a first material which is an organic semiconductor compound and a second material which is a different organic semiconductor compound.

In an embodiment, the second material has a spin doublet ground state.

In an embodiment, a lowest spin singlet excitation energy of the first material and a lowest spin triplet excitation energy of the first material are greater than a lowest spin doublet excitation energy of the second material.

The device is a light emitting diode device. In an embodiment, the device is configured such that during operation, energy is transferred from the spin singlet excited state in the first material and the spin triplet excited state in the first material to create excited doublet states in the second material, and light is subsequently emitted from the second material.

In an embodiment, the difference between the LUMO energy level of the first material and the SOMO energy level of the second material is less than 0.7 eV. In an embodiment, the difference between the LUMO energy level of the first material and the SOMO energy level of the second material is less than 0.5 eV. In an embodiment, the difference between the LUMO energy level of the first material and the SOMO energy level of the second material is less than 0.5 eV, less than 0.4 eV, less than 0.3 eV, or about 0.2 eV to 0.3 eV

In an embodiment, the second material is a compound that emits fluorescent light when transitioning from a lowest spin doublet excitation energy level to a ground energy level. In an embodiment, the emission has a lifetime for 90% of the emission of less than about 1 microsecond following photoexcitation, in a further embodiment less than about 0.8 microseconds, and in yet a further embodiment less than about 0.6 microseconds following photoexcitation.

In an embodiment, the absorption extinction coefficient of the second material for the lowest energy transition is greater than 1000 M⁻¹cm⁻¹, in a further embodiment greater than about 1500 M⁻¹cm⁻¹, in a yet further embodiment greater than about 2000 M⁻¹cm⁻¹

In an embodiment, a difference between the lowest spin singlet excitation energy level of the first material and the lowest spin doublet excitation energy of the second material is less than about 1.5 eV, in a further embodiment less than about 1.2 eV, and in a further embodiment less than about 1 eV, in yet a further embodiment less than about 0.7 eV.

In an embodiment, the difference between the lowest spin singlet excitation energy level of the first material and the lowest spin triplet excitation energy level of the first material is less than 0.2 eV.

In an embodiment, an amount of the first organic semiconductor compound in the emissive layer is greater than an amount of the second organic semiconductor compound in the emissive layer.

In an embodiment, the emissive layer comprises a third material which is an organic semiconductor compound, wherein a lowest spin singlet excitation energy level of the third material is greater than the lowest spin singlet excitation energy of the first material.

In an embodiment, the third material is doped with the second material with a concentration of less than or equal to 10% by weight and doped with the first material with a concentration of greater than or equal to 2% by weight, provided an amount of the first organic semiconductor compound in the emissive layer is greater than an amount of the second organic semiconductor compound in the emissive layer. In an embodiment, the third material is doped with the second material with a concentration of less than or equal to 5% by weight and doped with the first material with a concentration of greater than or equal to 5% by weight, provided an amount of the first organic semiconductor compound in the emissive layer is greater than an amount of the second organic semiconductor compound in the emissive layer.

In an embodiment, the first material is a thermally-activated delayed fluorescent (TADF) material. In an embodiment the first material is a compound having an electron deficient component and an electron rich component. In an embodiment the first material is one or more selected from the group consisting of:

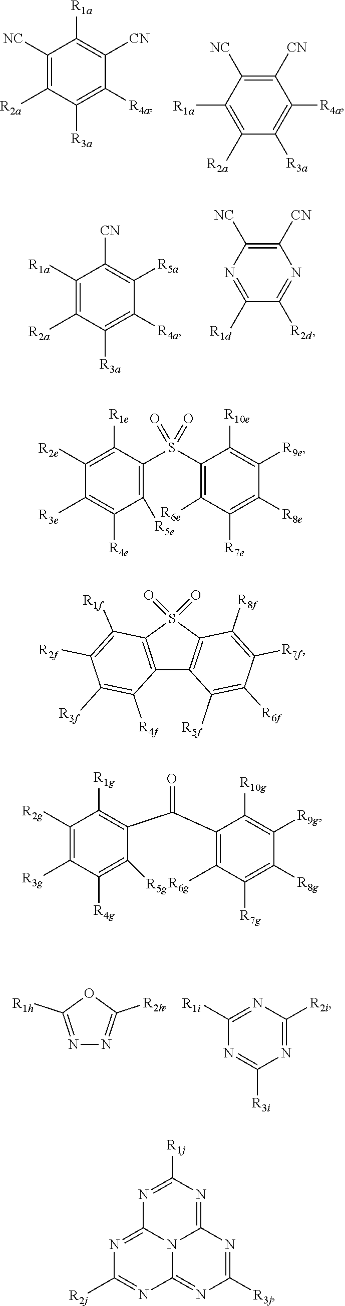

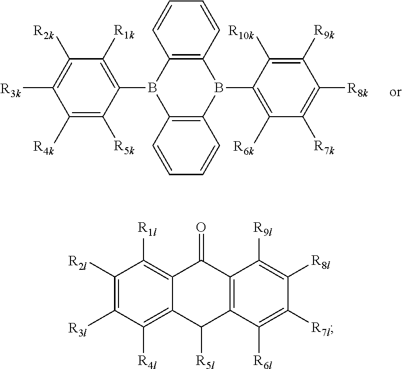

wherein R₁ₐ, R₂ₐ, R₃ₐ, R₄ₐ, R₅ₐ, R_{1d}, R_{2d}, R₁ₑ, R₂ₑ, R₃ₑ, R₄ₑ, R₅ₑ, R₆ₑ, R₇ₑ, R₈ₑ, R₉ₑ, R₁₀ₑ, R_{1f}, R_{2f}, R_{3f}, R_{4f}, R_{5f}, R_{6f}, R_{7f}, R_{8f}, R_{1g}, R_{2g}, R_{3g}, R_{4g}, R_{5g}, R_{6g}, R_{7g}, R_{8g}, R_{9g}, R_{10g}, R₁ₕ, R₂ₕ, R₁ᵢ, R₂ᵢ, R₃ᵢ, R₁ⱼ, R₂ⱼ, R₃ⱼ, R₁ₖ, R₂ₖ, R₃ₖ, R₄ₖ, R₅ₖ, R₆ₖ, R₇ₖ, R₈ₖ, R₉ₖ, R₁₀ₖ, R₁ₗ, R₂ₗ, R₃ₗ, R₄ₗ, R₅ₗ, R₆ₗ, R₇ₗ, R₈ₗ, R₉ₗ are independently selected from the groups consisting of H,

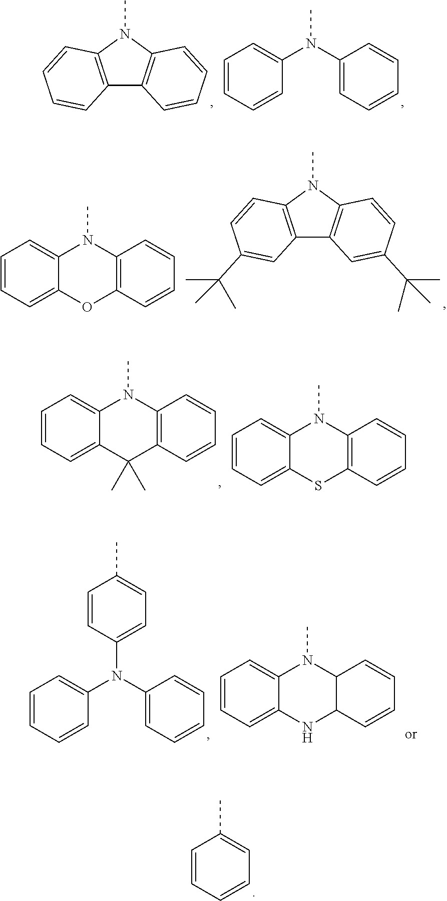

In an embodiment, the first material is one or more selected from the group consisting of: 10-(4-(4-(10H-Phenoxazin-10-yl)phenylsulfonyl)phenyl)-10H-phenoxazine (PXZ-DPS), 5,10-bis(4-(9H-carbazol-9-yl)-2,6-dimethylphenyl)-5,10-di hydroboranthrene (CzDBA) and 2,4,5,6-tetra(9H-carbazol-9-yl)isophthalonitrile (4CzIPN).

In an embodiment, the second material is a stable organic radical. In an embodiment, the second material comprises a donor moiety and an acceptor moiety. In an embodiment, the acceptor moiety is selected from the group consisting of:

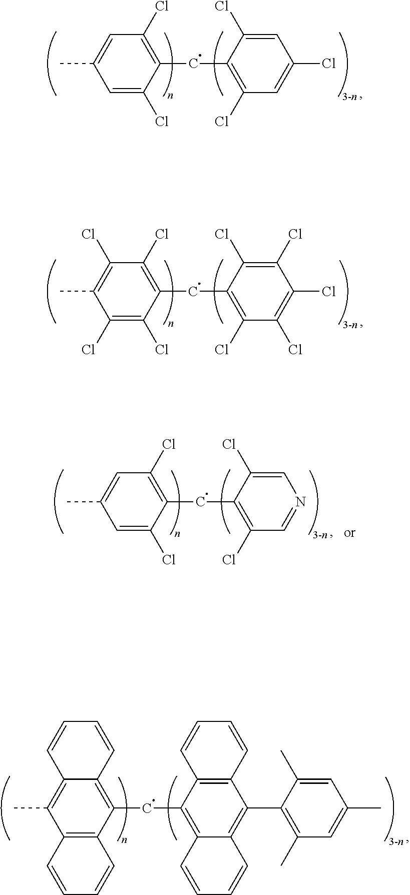

wherein n=1, 2 or 3 and _ _ _ _ _ _ indicates the point attachment to the donor moiety. In an embodiment, the acceptor moiety is a TTM radical.

In an embodiment, the donor moiety is selected from the group consisting of: _ _ _ _ _ _ H, _ _ _ _ _ _ Cl,

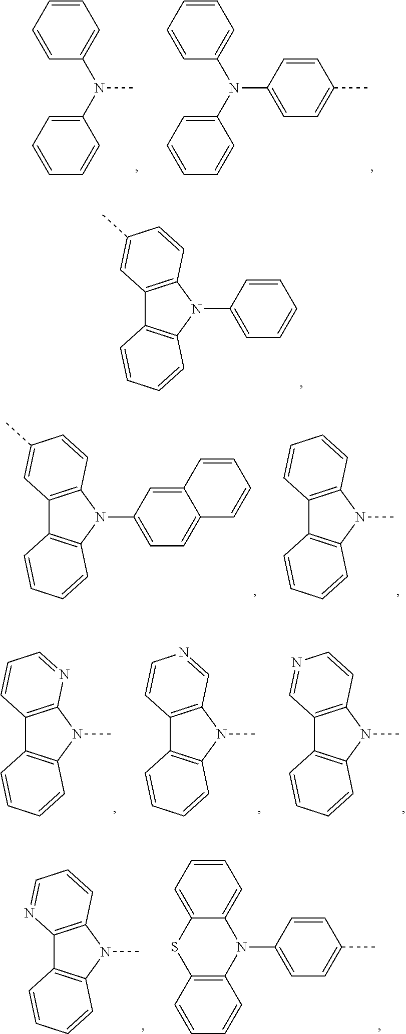

wherein _ _ _ _ _ _ indicates the point of attachment to the acceptor moiety.

In an embodiment, the second material is one or more selected from the group consisting of:

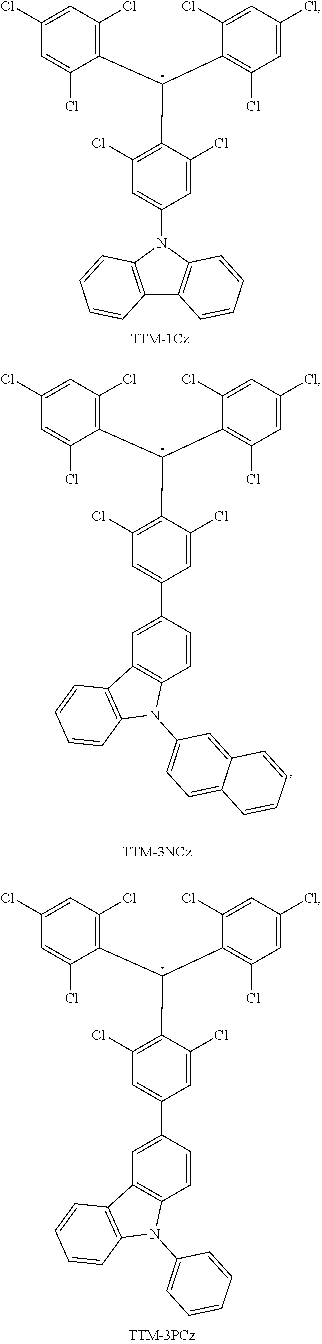

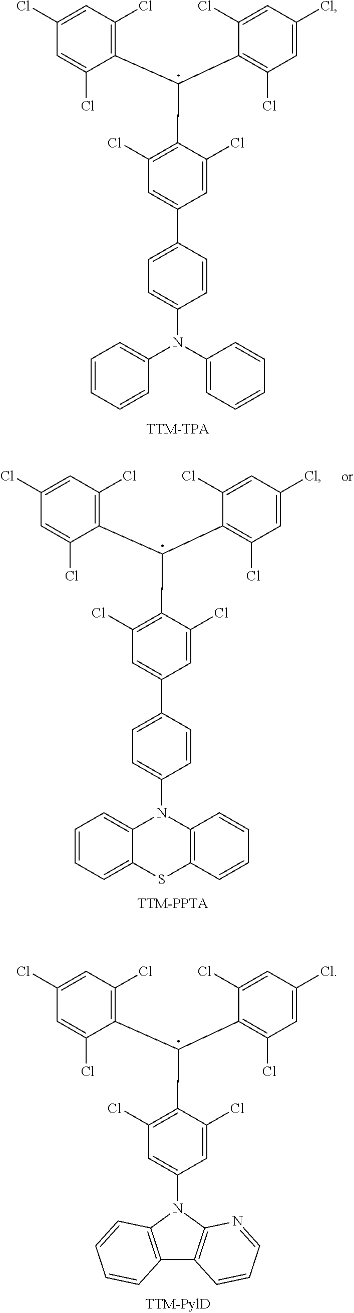

In an embodiment, the external quantum efficiency (EQE) of the device at 1 mA/cm² is greater than 0.65 of the maximum EQE. In an embodiment, the external quantum efficiency (EQE) of the device at 1 mA/cm² is greater than 0.70 of the maximum EQE, or even greater than 0.75, 0.80, or 0.85 of the maximum EQE. In an embodiment, the external quantum efficiency (EQE) of the device at 1 mA/cm² is greater than 0.90 of the maximum EQE, or even greater than 0.95 or 0.99 of the maximum EQE. In an embodiment, the external quantum efficiency (EQE) of the device at 10 mA/cm² is greater than 0.65 of the maximum EQE. In an embodiment, the external quantum efficiency (EQE) of the device at 10 mA/cm² is greater than 0.70 of the maximum EQE, or even greater than 0.75, 0.80, or 0.85 of the maximum EQE.

In an embodiment, the LUMO of the material forming the layer adjacent to the emissive layer and between the emissive layer and the cathode is higher energy than, i.e. has a smaller magnitude than, the LUMO of the first material. In this embodiment, the difference between the LUMO of this material and the LUMO of the first material is about 0.1 eV to 0.5 eV, about 0.2 eV to 0.4 eV or about 0.1 eV to 0.2 eV. In another embodiment, the LUMO of this material is about the same in energy as the LUMO of the first material i.e. the difference between the LUMO of this material and the LUMO of the first material is less than about 0.1 eV.

In an embodiment, the emissive layer comprises a third material which is an organic semiconductor compound, and the device is configured such that during operation the first material and the third material form an exciplex. The emissive layer comprises an exciplex host which is a combination of the first material and the third material, that combine together to form an exciplex.

The exciplex has a lowest spin singlet excitation energy and a lowest spin triplet excitation energy that are greater than a lowest spin doublet excitation energy of the second material. During operation, energy is transferred from the spin singlet excited state in the exciplex and the spin triplet excited state in the exciplex to the second material.

In an embodiment, the first material and the third material form a charge transfer system. In an embodiment, the first material and the third material form a thermally-activated delayed fluorescent (TADF) host. In an embodiment, the first material is a hole transport compound. In an embodiment, the first material is an electron-rich material. In an embodiment, the third material is an electron transport compound. In an embodiment, the third material is an electron-deficient material. The first material may be tris(4-carbazoyl-9-ylphenyl)amine (TCTA), 9,9′-Diphenyl-9H,9′H-3,3′-bicarbazole (BCzPh), 1,1-Bis[(di-4-tolylamino)phenyl]cyclohexane (TAPC), 9-Phenyl-3,6-bis(9-phenyl-9Hcarbazol-3-yl)-9H-carbazole (Tris-PCz), 1,3-bis(9-carbazolyl)benzene (mCP), 4,4′-bis(N-carbazolyl)-1,1′-biphenyl (CBP), 3,3-bis(carbazol-9-yl)biphenyl (mCBP), N,N′-di(1-naphthyl)-N,Nr-diphenyl-(1,1′-biphenyl)-4,4′-diamine (NPB), 4,4′,4″-tris[phenyl(m-tolypamino]triphenylamine (m-MTDATA), and N,N′-bis(3-methylphenyl)-N,N′-diphenylbenzidine (TPD) for example. The third material may be bis-4,6-(3,5-di-2-pyridylphenyl)-2-methylpyrimi-dine (B2PYM PM), bis-4,6-(3,5-di-3-pyridylphenyl)-2-methylpyrimi-dine (B3PYMPM), bis-4,6-(3,5-di-4-pyridylphenyl)-2-methylpyrimi-dine (B4PYMPM), bis-4,6-(3,5-di(pyridin-4-Aphenyl)-2-phenylpyrimidine (B4PYPPM), 3-(4,6-Diphenyl-1,3,5-triazin-2-yl)-9-phenyl-9H-carbazole (DPTPCz), 2,4,6-tris(iphenyl-3-yl)-1,3,5-triazine (T2T), 2,2′,2″-(1,3,5-benzenetriyl)tris[1-phenyl-1H-benzimidazole] (TPBi), tris(2,4,6-trimethyl-3-(pyridin-3-yl)phenyl)borane (3TPYMB), 1,3-bis[3,5-di(pyridin-3-yl) phenyl]benzene (BmPyPB), 1,3-bis[3,5-di(pyridin-3-yl)phenyl]benzene (BmPyPhB), 3,3′,5,5′-tetra[(M-pyridyl)-phen-3-yl]biphenyl (BP4mPy), 3,3′[5′[3-(3-pyridinyl)phenyl][1,1′:3′,1″-terphenyl]-3,3′-diyl]bispyridine (TmPyPB), bis-9,9′-spirobi[fluoren-2-yl]-methanone (BSFM), (1,3,5-Triazine-2,4,6-triyl)tris(benzene-3,1-diyl)tris(diphenylphosphine oxide) (PO-T2T), and dibenzo[b,d]thiophene-2,8-diylbis(diphenylphosphine oxide) (PO15) for example. In an embodiment, the first material and the third material include conjugated pi systems.

In an embodiment, the emissive layer comprises the first material and the third material in a combined amount of from about 90% to about 99% by weight based on the total weight of the emissive layer. In an embodiment, the emissive layer comprises the first material and the third material in a combined amount of about 97% by weight based on the total weight of the emissive layer. In an embodiment, the emissive layer comprises the third material that is doped with the first material with a concentration of greater than about 20% by weight. In an embodiment, the ratio of the first material to the third material in the emissive layer is about 1:1. In an embodiment, the emissive layer comprises the second material in an amount of from about 1% to about 10% by weight based on the total weight of the emissive layer. In an embodiment, the emissive layer comprises the second material in an amount of about 3% by weight based on the total weight of the emissive layer.

In an embodiment, the energy of the lowest unoccupied molecular orbital of the first material is higher than the energy of the lowest unoccupied molecular orbital of the third material, and the energy of the highest occupied molecular orbital of the first material is higher than the energy of the highest occupied molecular orbital of the third material. In an embodiment, the energy of the highest occupied molecular orbital of the first material is lower than the energy of the lowest unoccupied molecular orbital of the third material.

In an embodiment, the energy difference between the highest occupied molecular orbital of the first material and the lowest unoccupied molecular orbital of the third material is greater than the lowest spin doublet excitation energy of the second material.

In an embodiment, the LUMO energy level of the third material is higher than the SOMO energy level of the second material for reduction. This reduces charge transfer, specifically electron transfer, from the radical to the third material following excitation. In an embodiment, the HOMO energy level of the first material is lower energy than the HOMO energy level of the second material. This reduces charge transfer, specifically hole transfer, from the radical to the first material following excitation.

In an embodiment a difference between the lowest spin singlet excitation energy level of the exciplex and the lowest spin doublet excitation energy of the second material is less than 1.5 eV. In an embodiment, the difference between the lowest spin singlet excitation energy level of the exciplex and the lowest spin triplet excitation energy level of the exciplex is less than 0.2 eV.

In an embodiment, the lowest spin singlet excitation energy and the lowest spin triplet excitation energy of the first material is higher than the lowest spin singlet excitation energy and the lowest spin triplet excitation energy of the exciplex.

In an embodiment, the lowest spin triplet excitation energy and the lowest spin triplet excitation energy of the third material is higher than the lowest spin singlet excitation energy and the lowest spin triplet excitation energy of the exciplex.

According to an embodiment, there is provided a method of fabricating an organic light emitting device, comprising:
forming an emissive layer between an anode and a cathode, wherein the emissive layer comprises a first material which is an organic semiconductor compound and a second material which is a different organic semiconductor compound.

In an embodiment, the second material has a spin doublet ground state.

In an embodiment, a lowest spin singlet excitation energy of the first material and a lowest spin triplet excitation energy of the first material are greater than a lowest spin doublet excitation energy of the second material.

According to an embodiment, there is provided a method of operating an organic light emitting device comprising an anode, a cathode, and an emissive layer between the anode and the cathode, wherein the emissive layer comprises a first material which is an organic semiconductor compound and a second material which is a different organic semiconductor compound that has a spin doublet ground state, the method comprising:
applying a voltage across the device, such that spin singlet excited states and spin triplet excited states are formed for the first material, wherein energy is transferred from spin singlet excited states in the first material and spin triplet excited states in the first material to form spin doublet excited states in the second material, wherein the second material emits fluorescent light when transitioning from a spin doublet excited state to a ground state.

According to an embodiment, there is provided an organic light emitting device, comprising:
an anode;
a cathode; and
an emissive layer between the anode and the cathode, wherein the emissive layer comprises:
   a host, comprising a combination of a first material, which is an organic semiconductor compound, and a third material, which is a different organic semiconductor compound, and
   a second material, which is a different organic semiconductor compound that has a spin doublet ground state;
wherein a lowest spin singlet excitation energy of the host and a lowest spin triplet excitation energy of the host are greater than a lowest spin doublet excitation energy of the second material.

During operation, energy is transferred from the spin singlet excited state in the host and the spin triplet excited state in the host to the second material.

In an embodiment, the host comprises a charge transfer system. In an embodiment, the host is a thermally-activated delayed fluorescent (TADF) host. In an embodiment, the host is an exciplex host which is a combination of the first material and the third material.

In an embodiment, the first material is a hole transport compound. In an embodiment, the first material is an electron-rich material. The first material may be 4,4-bis(carbazol-9-yl)biphenyl (CBP) or tris(4-carbazoyl-9-ylphenyl)amine (TCTA).

In an embodiment, the third material is an electron transport compound. In an embodiment, the third material is an electron-deficient material. The third material may be 2,2′,2″-(1,3,5-benzinetriyl)-tris(1-phenyl-1-H-benzimidazole) (TPBi) or 4,6-Bis(3,5-di(pyridin-3-yl)phenyl)-2-methylpyrimidine (B3PYMPM) for example.

In an embodiment, the first material and the third material include conjugated pi systems.

In an embodiment, the emissive layer comprises the first material and the third material in a combined amount of from about 90% to about 99% by weight based on the total weight of the emissive layer. In an embodiment, the emissive layer comprises the first material and the third material in a combined amount of about 97% by weight based on the total weight of the emissive layer. In an embodiment, the ratio of the first material to the third material in the emissive layer is about 1:1. In an embodiment, the emissive layer comprises the second material in an amount of from about 1% to about 10% by weight based on the total weight of the emissive layer. In an embodiment, the emissive layer comprises the second material in an amount of about 3% by weight based on the total weight of the emissive layer. In an embodiment, an amount of the host in the emissive layer is greater than an amount of the second material in the emissive layer.

In an embodiment, the energy of the lowest unoccupied molecular orbital (LUMO) of the first material is higher than the energy of the lowest unoccupied molecular orbital of the third material, and the energy of the highest occupied molecular orbital of the first material is higher than the energy of the highest occupied molecular orbital (HOMO) of the third material. In an embodiment, the energy of the highest occupied molecular orbital of the first material is lower than the energy of the lowest unoccupied molecular orbital of the third material.

In an embodiment, the energy difference between the highest occupied molecular orbital of the first material and the lowest unoccupied molecular orbital of the third material is greater than the lowest spin doublet excitation energy of the second material.

In an embodiment, the LUMO energy level of the third material is higher than the SOMO energy level of the second material for reduction. In an embodiment, the HOMO energy level of the first material is lower than the HOMO energy level of the second material.

In an embodiment, the device is configured such that during operation the first material and the third material form an exciplex, wherein a lowest spin singlet exciplex excitation energy and a lowest spin triplet exciplex excitation energy are greater than a lowest spin doublet excitation energy of the second material. During operation, energy is transferred from the spin singlet excited state in the exciplex and the spin triplet excited state in the exciplex to create excited doublet states in the second material, and light is subsequently emitted from the second material.

In an embodiment, the lowest spin singlet excitation energy and the lowest spin triplet excitation energy of the first material is higher than the lowest spin singlet excitation energy and the lowest spin triplet excitation energy of the exciplex.

In an embodiment, the lowest spin singlet excitation energy and the lowest spin triplet excitation energy of the third material is higher than the lowest spin singlet excitation energy and the lowest spin triplet excitation energy of the exciplex.

In an embodiment, a difference between the lowest spin singlet excitation energy level of the exciplex and the lowest spin doublet excitation energy of the second material is less than 1.5 eV. In an embodiment, he difference between the lowest spin singlet excitation energy level of the exciplex and the lowest spin triplet excitation energy level of the exciplex is less than 0.2 eV.

In an embodiment, the second material is a compound that emits fluorescent light when transitioning from a lowest spin doublet excitation energy level to a ground energy level, with a lifetime for 90% of the emission of less than 1 microsecond following photoexcitation.

In an embodiment, wherein the absorption extinction coefficient of the second material for the lowest energy transition is greater than 1000 M⁻¹cm⁻¹.

In an embodiment, the second material is a stable organic radical. In an embodiment, the second material comprises a donor moiety and an acceptor moiety. The acceptor moiety may be selected from the group consisting of:

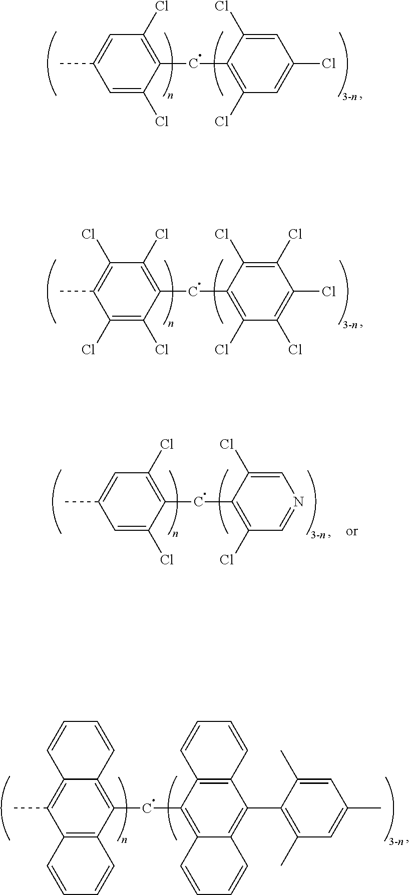

wherein n=1, 2 or 3 and _ _ _ _ _ _ indicates the point attachment to the donor moiety. The acceptor moiety may be a TTM radical. The donor moiety may be selected from the group consisting of: _ _ _ _ _ _ H, _ _ _ _ _ _ Cl,

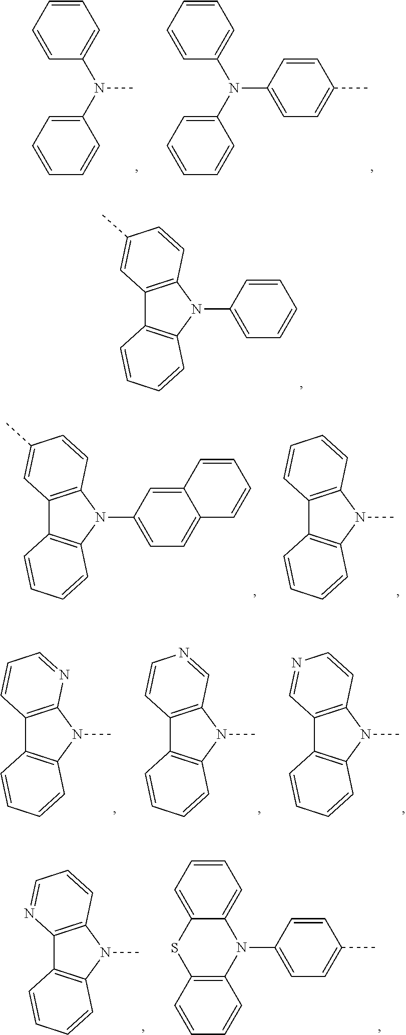

wherein _ _ _ _ _ _ indicates the point of attachment to the acceptor moiety.

In an embodiment, the second material is one or more selected from the group consisting of:

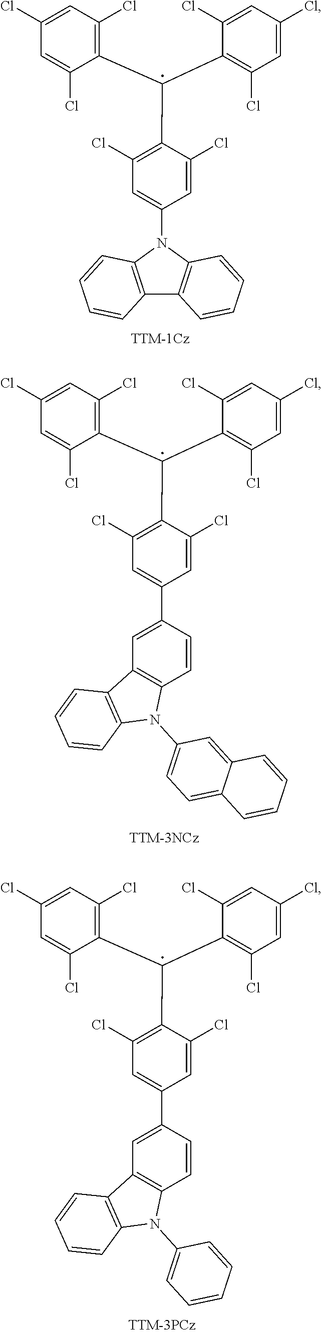

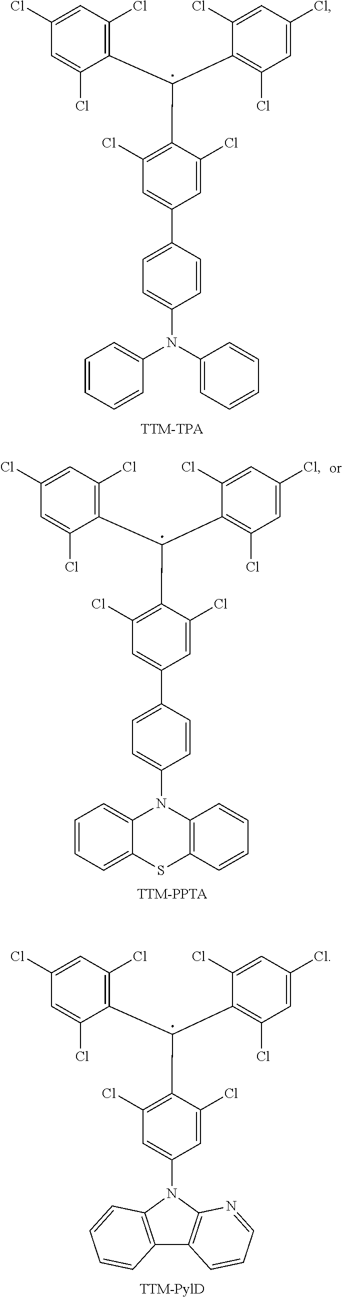

According to an embodiment, there is provided a method of fabricating an organic light emitting device, comprising:
forming an emissive layer between an anode and a cathode, wherein the emissive layer comprises a host comprising a first material, and a dopant comprising a second different material that has a spin doublet ground state; and
wherein a lowest spin singlet excitation energy of the host and a lowest spin triplet excitation energy of the host are greater than a lowest spin doublet excitation energy of the dopant.

According to an embodiment, there is provided a method of operating an organic light emitting device comprising an anode, a cathode, and an emissive layer between the anode and the cathode, wherein the emissive layer comprises a host comprising a first material, and a dopant comprising a second different material that has a spin doublet ground state, the method comprising:
applying a voltage across the device, such that spin singlet excited states and spin triplet excited states are formed in the host, wherein energy is transferred from the spin singlet excited states and the spin triplet excited states to form spin doublet excited states in the dopant, wherein the dopant emits fluorescent light when transitioning from a spin doublet excited state to a ground state.

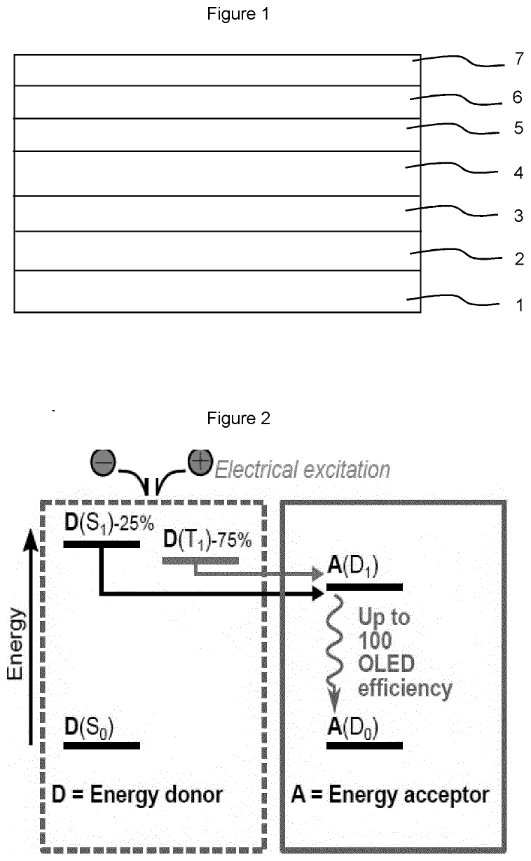

FIG. 1 shows a schematic illustration of an organic light emitting device in accordance with an embodiment. The device is a light emitting diode. The device comprises an anode 1 and a cathode 6. The device further comprises an emissive layer 4 between the anode 1 and the cathode 6. The device shown in FIG. 1 comprises further layers included between the anode 1 and the cathode 6, which will be described below. However, in general the device may comprise an anode 1, a cathode 6, an emissive layer 4, and may optionally comprise one or more further layers. The organic light emitting device may be formed on a substrate (not shown). Various types of substrate are known for use in organic light emitting devices, including transparent materials such as glass or quartz or flexible polymers for example, and any of these known substrate materials may be used in the device.

### First Embodiment

In a first embodiment, the emissive layer 4 comprises a first material which is an organic semiconductor compound and a second material which is a different organic semiconductor compound. The first material is also referred to as the donor material D and the second material is also referred to as the acceptor material A. The first material is a closed shell molecule and has a singlet spin 0 ground state. The spin singlet ground state is referred to as S₀. The second material is an open shell molecule and has a spin doublet ground state. The spin doublet ground state is referred to as D₀. The second material comprises a singly occupied molecular orbital (SOMO) in the ground state, giving an overall spin-½ doublet ground state. The emissive layer 4 may comprise one or more additional materials, for example a third material which acts as a host material. The third material may be a closed shell molecule. The third material may be an organic semiconductor compound.

During operation, a voltage is applied across the device. Electrons are injected from the cathode and holes are injected from the anode. Charge trapping occurs at the first material molecule sites. Holes and electrons occupy the highest occupied molecular orbitals (HOMOs) and lowest unoccupied molecular orbitals (LUMOs) in the first material, and recombine to form singlet or triplet excitons. Electrical excitation leads to the formation of singlet spin 0 excitons with 25% probability and triplet spin 1 excitons with 75% probability. The spin singlet excited state is referred to as S₁ and the spin triplet excited state is referred to as T₁.

Energy from the first material in the excited state is transferred to the second material. The second material is transferred from the spin doublet ground state to the spin doublet excited state. The spin doublet excited state is referred to as D₁. The second material then emits fluorescent light on returning to the spin doublet ground state. The second material is a doublet emitter. Spin-allowed emission, i.e. fluorescence, in the molecules of the second material originates from the lowest-lying doublet excited state. The second material may be a radical emitter. Examples of the second material will be described below.

During operation, a voltage is applied across the device, forming spin singlet excited states and spin triplet excited states in the first material, wherein energy is transferred from the spin singlet excited state in the first material and the spin triplet excited state in the first material to create an excited doublet state in the second material, wherein the second material emits fluorescent light transitioning from a spin doublet excited state to a ground state.

The LUMO energy level of the first material is higher than, i.e. has a smaller magnitude than, the SOMO energy level of the second material. Selecting a first material in which the LUMO energy level is closer to the SOMO energy level of the second material increases the probability of charge trapping occurring on the first material in preference to the second material. In an embodiment, the difference between the LUMO energy level of the first material and the SOMO energy level of the second material is less than 0.7 eV. In a further embodiment, the difference between the LUMO energy level of the first material and the SOMO energy level of the second material is less than 0.5 eV, less than 0.4 eV, less than 0.3 eV, or about 0.2 eV to 0.3 eV.

In an embodiment, the difference between the HOMO energy of the first material and the HOMO energy of the second material is less than 0.7 eV. In a further embodiment, the difference between the HOMO energy of the first material and the HOMO energy of the second material is less than 0.5 eV, or less than 0.4 eV.

Increasing the % wt of the first material in the emissive layer relative to the % wt of the second material in the emissive layer also acts to increase the probability of charge trapping occurring on the first material. An amount of the first organic semiconductor compound in the emissive layer is greater than an amount of the second organic semiconductor compound in the emissive layer. When the donor is in excess versus the acceptor material, the charge trapping is more likely at the donor sites. This is a kinetic effect, resulting in electron-hole recombination preferentially occurring at the donor sites.

It is considered that Dexter-type energy transfer occurs from the spin triplet excitons to the spin doublet ground state:

D(T₁)+A(D₀)→D(S₀)+A(D₁)

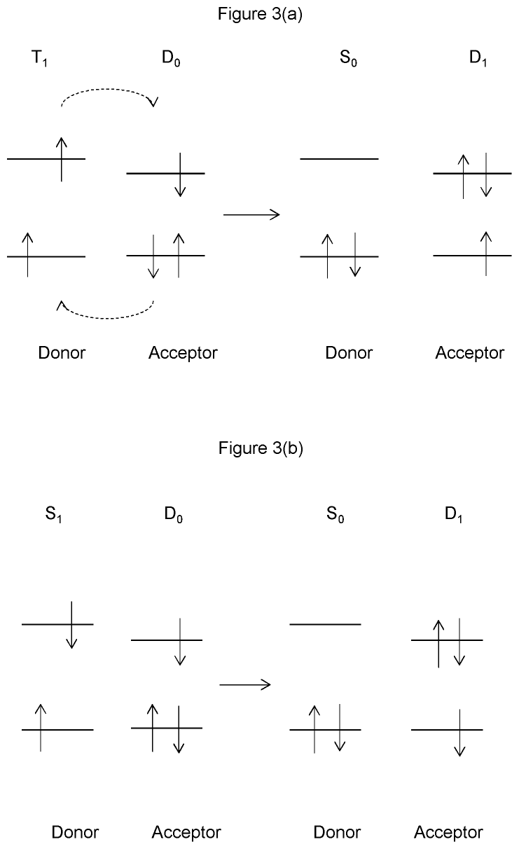

Dexter energy transfer is a mechanism in which an excited electron is transferred from a donor molecule to an acceptor molecule, in exchange for a ground-state electron being transferred from the acceptor molecule to the donor molecule. The exchange may occur in a single step, or in two separate steps. FIG. 3(a) shows a schematic illustration of a Dexter energy transfer process in which an excited electron is transferred from the donor molecule in the spin triplet excited state to the acceptor molecule in the spin doublet ground state, forming a spin doublet excited state, and a ground state electron is transferred from the acceptor molecule in the spin doublet ground state to the donor molecule in the spin triplet excited state, forming a spin singlet ground state. The doublet spin property allows Dexter-type energy transfer from triplet excitons. The Dexter transfer process occurs on a sub-microsecond timescale.

The lowest spin triplet excitation energy of the first material is greater than the lowest spin doublet excitation energy of the second material. This permits Dexter energy transfer to occur from the spin triplet excitons to the spin doublet ground state. Thermodynamically, the lowest energy excited state is the spin doublet excited state, so energy transfer occurs from the first material to the second material.

Dexter transfer occurs via an electron exchange mechanism with wavefunction overlap between the donor molecule and acceptor molecule. For this reason, the transfer efficiency is dependent on the distance between the donor and acceptor molecules; it follows an e^{-d} dependence where d is the intermolecular separation.

The amount of the first material and the second material in the emissive layer 4 may be selected in order to increase the efficiency of Dexter transfer between the spin triplet excited state in the first material and the spin doublet ground state in the second material. In particular, an amount of the first organic semiconductor compound in the emissive layer is greater than an amount of the second organic semiconductor compound in the emissive layer.

It is considered that Förster-type energy transfer occurs from the spin singlet excitons to the spin doublet ground state. Förster transfer occurs between the closed-shell molecule, i.e. the energy donor D and the open-shell molecule, i.e. the energy acceptor A:

D(S₁)+A(D₀)→D(S₀)+A(D₁)

This Förster-type energy transfer involves open-shell, doublet emitters A. The Förster transfer process also occurs on a sub-microsecond timescale.

A lowest spin singlet excitation energy of the first material is greater than a lowest spin doublet excitation energy of the second material. This permits Förster transfer to occur from the first material to the second material. Thermodynamically, the lowest energy excited state is the spin doublet excited state, so energy transfer occurs from the first material to the second material.

The efficiency of the singlet-doublet energy transfer is improved when the radical material is a good absorber. The efficiency of the singlet-doublet energy transfer is increased with higher absorption extinction coefficient. In an embodiment, the absorption extinction coefficient ε of the second material for the lowest energy transition is greater than 1000 M⁻¹ cm⁻¹. The absorption extinction coefficient ε of the second material is increased when the energy gaps for the HOMO-SOMO transition and the SOMO-LUMO transition are not degenerate, leading to higher oscillator strength. This is the case for radical materials having a “donor-acceptor” structure for example. In radical materials, a donor-acceptor character of the molecule breaks the degeneracy of the HOMO-SOMO and SOMO-LUMO energy gaps. When the energy gaps for the HOMO-SOMO transition and the SOMO-LUMO transition are degenerate, the lowest excited state emission is a dipole-cancelling out-of-phase combination of the two transitions and the oscillator strength is lower.

The efficiency of the Förster transfer occurring between the first material in the spin singlet excited state and the second material in the spin doublet ground state is increased with increased overlap of the donor emission spectrum with the acceptor absorption spectrum. Increased spectral overlap between the donor S₁ fluorescence with the doublet absorption provides increased efficiency of the singlet-doublet energy transfer.

As for the Dexter transfer, transfer efficiency of the Förster transfer occurring between the first material in the spin singlet excited state and the second material in the spin doublet ground state is also increased with reduced distance between the molecules of the first material and the second material. The transfer efficiency follows a d⁻⁶ dependence where d is the intermolecular separation.

As explained above, for the first material and the second material, the following expression (i) is satisfied:

E_{S1}(D)>E_{D1}(A), E_{T1}(D)>E_{D1}(A) (i)

In expression (i), E_{S1}(D) represents the lowest spin singlet excitation energy level of the first material, E_{T1}(D) represents the lowest spin triplet excitation energy level of the first material, and E_{D1}(A) represents the lowest spin doublet excitation energy of the second material.

FIG. 2 shows a schematic illustration of the mechanism occurring in the emissive layer 4 when a voltage is applied, as in the process described above. Charge trapping occurs at the first material, which is a closed-shell compound D, to form singlet S₁ and triplet T₁ excitons. Due to the doublet-spin nature of the second material, which is an open-shell compound A, the energy from both singlet and triplet excitons can be transferred to A directly, during device operation. The doublet emitters A receive energy to form doublet-spin excitons D₁ for light emission. The mode of operation comprises: charge trapping at D, closed-shell molecule sites form singlet and triplet excitons which can undergo direct energy transfer to the doublet emitter A to generate luminescent doublet excitons. Since energy is harvested from both the triplet and singlet excited states, this mode of operation is believed to have possible electroluminescence efficiency of up to 100%.

As has been explained above, for closed-shell molecules with a singlet spin 0 ground state, electrical excitation leads to the formation of 25% singlet spin 0 and 75% triplet spin 1 excitons. This scenario should lead to a maximum possible electroluminescence efficiency of 25%, as singlet and triplet states are bright and dark to first order. By harvesting energy from the spin triplet excited state, efficiency of the OLED device may therefore be improved.

Luminescence may be recovered from the spin triplet excited state T₁ by an E-type delayed fluorescence mechanism, equivalent to thermally activated delayed fluorescence. In a TADF mechanism, delayed fluorescence from S₁ follows reverse intersystem coupling (T₁ to S₁). This is described in Uoyama, H., Goushi, Ki., et al., Nature; 492, 234-238 (2012) 10.1038/nature11687, the entire contents of which, including the extended data and supplementary information, are incorporated herein by reference. However, despite having the potential to overcome the spin statistics problem, delayed fluorescence may be associated with lifetimes of microseconds and longer. This can lead to poor device stability and roll-off, i.e. a drop in electroluminescent efficiency with increasing current density.

Combining TADF and organic fluorescent (F) molecules is sometimes referred to as ‘hyperfluorescence’. In such devices, charge trapping happens at the TADF molecule sites to generate singlet and triplet excitons. Förster-type energy transfer follows the singlet channel from (TADF) D (S₁) to F (S₁) and device light emission occurs from F (S₁), in the process D (S₁)+F (S₀)→D (S₀)+F (S₁). This process involves Förster-type singlet energy transfer between two closed-shell molecules, an energy donor species, D, which is a TADF molecule and a fluorescent molecule, F. The equivalent energy transfer from the T₁ triplet exciton state of D is inefficient, due to a lower radiative rate associated with the phosphorescence. There is however an indirect, delayed transfer of energy from the triplet excitons via reverse ISC from TADF (T₁) to TADF (S₁), then Förster transfer to F (S₁). Such devices may also have microsecond delayed fluorescence however.

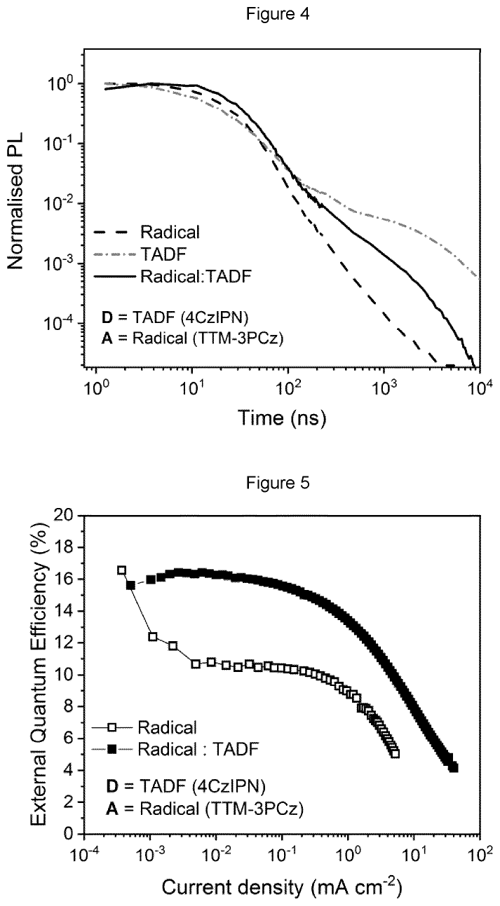

In the device described in relation to FIG. 1 above, emission occurs from a spin doublet excited state. Given the doublet-spin ground state of the acceptor molecules, light emission from D₁ is spin-allowed i.e. fluorescence. The fluorescence may be associated with lifetimes of less than 100 nanoseconds. FIG. 4 shows experimental data of transient photoluminescence measurements for various materials, showing the normalised photoluminescence intensity on the y axis, with time on x axis. The measurements of FIG. 4 show the radiative decay of the excited states. The dashed-dotted line shows the intensity for a TADF material, 2,4,5,6-tetra(9H-carbazol-9-yl)isophthalonitrile, referred to as 4CzIPN (averaged 500-600 nm). This film contains 25% 4CzIPN doped in CBP (thickness=150 nm) and is labelled “TADF” in FIG. 4. The dashed line shows the intensity profile (averaged 700-800 nm) for an open shell radical molecule having a spin doublet ground state, in this case a molecule in which 3-substituted-9-phenyl-9H-carbazole (3PCz) is incorporated to tris(2,4,6-trichlorophenyl)methyl (TTM). The molecule is referred to as TTM-3PCz and is labelled in the figure as “Radical.” The Radical film contains 3% TTM-3PCz in CBP (thickness=300 nm). As can be seen, the Radical undergoes faster radiative decay than the TADF molecule. For the Radical, 90% of its total emission occurs by 70 ns after photoexcitation. For the TADF, 90% of its total emission occurs by 5.2 μs after photoexcitation. 53% of the total emission for the TADF occurs later than 100 ns.

However, devices in which charge trapping occurs on the doublet molecule sites may have steep efficiency roll-off, i.e. a drop in electroluminescent efficiency with increasing current density. It is considered that this may be attributed to charge balance difficulties in the device. In the device described in relation to FIG. 1 above, the charge trapping process is moved away from the doublet emitters, and therefore good charge balance may be obtained resulting in operational stability. Charge trapping occurs at a first material which is a closed-shell compound D, energy from both singlet and triplet excitons are transferred to a second material which is an open shell compound A, and doublet emitters form doublet-spin excitons D₁ for light emission. Good operational stability may be achieved.

FIG. 5 shows experimental data in which the external quantum efficiency (EQE) is shown on the y-axis, against current density on the x-axis, for various materials. The solid squares show the data for a device according to Example 1, which will be described in detail below. In Example 1, the emissive layer comprises a first material which is 4CzIPN (a closed shell molecule) and a second material which is TTM-3PCz (an open shell molecule having a doublet spin ground state). The first and second materials are doped into a third material, CBP. 4CzIPN is an example of a TADF material. The open squares show the data for a device according to a First Comparative Example which will also be described below, in which the emissive layer comprises CBP and TTM-3PCz. As can be seen, the drop in EQE occurs at higher current density for the device of Example 1 than for the device of Comparative Example 1. A maximum EQE value for the device of Example 1 of 16% is obtained at 1 μA/cm². An EQE value of 13% is found at 1 mA/cm². For the device of the First Comparative Example, a maximum EQE value of 17% is obtained, whilst an EQE of 13% is obtained at 1 μA/cm². An EQE value of 9% is found at 1 mA/cm².

FIG. 4 additionally shows the transient photoluminescence of the combination of 25% 4CzIPN and 3% TTM-3PCz in CBP (film thickness=150 nm), labelled “Radical: TADF”. This film was prepared by thermal vacuum deposition using the same conditions described for “3% TTM-3PCz: 97% CBP” and “25% 4CzIPN: 75% CBP” above. As can be seen, although the decay is slower than for TTM-3PCz, a faster decay than for 4CzIPN is still obtained. For the radical:TADF blend, 90% of the total emission occurs by 300 ns after photoexcitation. 19% of the total emission occurs later than 100 ns for the radical:TADF blend, signifying a reduced delayed component compared to the TADF (“25% 4CzIPN: 75% CBP”).

The timescale for overall emission can be reduced by more efficient energy transfer from the donor material (TADF in this case) to the acceptor (radical) material.

In an embodiment, a luminescence lifetime of less than 1 microsecond may be obtained, measured using a pulsed-laser excitation source at 400 nm and an intensified-CCD (ICCD) camera for time-resolved photoluminescence detection of the excited film. In an embodiment, a luminescence lifetime of less than 100 nanoseconds may be obtained. In an embodiment, a luminescence lifetime of 10 to 100 nanoseconds may be obtained.

In the device described in relation to FIG. 1 above, charge trapping occurs at the first material, and energy from both singlet and triplet excitons is transferred to the second material. The second material then emits fluorescent light on returning to the spin doublet ground state. Doublet spin ½ emitter molecules can therefore be used to harvest energy during organic electroluminescent device operation. This may result in increased efficiency and improved roll-off characteristics. Using doublet emitters to harvest energy from both singlet and triplet excitons directly in an electroluminescent device may reduce device instability and charge balance issues associated with direct charge trapping on the doublet emitters.

In the device described in relation to FIG. 1 above, emission occurs from a spin doublet excited state. As shown in FIG. 7, in a device according to an embodiment in which emission occurs from a spin doublet excited state, a FWHM of less than or equal to 100 nm may be obtained. This may be attractive for display technologies for example.

As described above, the lowest spin singlet excitation energy level of the first material is greater than the lowest spin doublet excitation energy of the second material. Selecting a first material in which the lowest spin singlet excitation energy level is closer to the lowest spin doublet excitation energy of the second material may increase the efficiency of the device. In an embodiment, the difference between the lowest spin singlet excitation energy level of the first material and the lowest spin doublet excitation energy of the second material is less than 1.5 eV. In a further embodiment, a difference between the lowest spin singlet excitation energy level of the first material and the lowest spin doublet excitation energy of the second material is less than 1.2 eV. In a yet further embodiment, a difference between the lowest spin singlet excitation energy level of the first material and the lowest spin doublet excitation energy of the second material is less than 1 eV. In a yet further embodiment, a difference between the lowest spin singlet excitation energy level of the first material and the lowest spin doublet excitation energy of the second material is less than 0.7 eV.

As has been described above, in the device of FIG. 1, the emissive layer comprises the first material and the second material. In an embodiment, an amount of the first organic semiconductor compound in the emissive layer is greater than an amount of the second organic semiconductor compound in the emissive layer. This reduces the probability of charge trapping occurring on the second material molecule sites, thereby increasing the probability of charge trapping occurring on the first material molecule sites.

The emissive layer 4 may further comprise a third material. The third material is an organic semiconductor. The third material may also be a closed shell molecule having a spin singlet ground state. The lowest spin singlet excitation energy level of the third material is greater than the lowest spin singlet excitation energy of the first material. In an embodiment, a difference between the lowest spin singlet excitation energy level of the third material and the lowest spin singlet excitation energy of the first material is greater than 0.7 eV. In an embodiment, a difference between the lowest spin singlet excitation energy level of the third material and the lowest spin singlet excitation energy of the first material is greater than or equal to 0.9 eV.

The LUMO energy level of the third material is higher than, i.e. has a smaller magnitude than, the LUMO energy level of the first material. Selecting a third material in which the LUMO energy level is further from the LUMO energy level of the first material increases the probability of charge trapping occurring on the first material in preference to the third material. In an embodiment, the difference between the LUMO energy level of the third material and the LUMO energy level of the first material is greater than 0.7 eV. In a further embodiment, the difference between the LUMO energy level of the third material and the LUMO energy level of the first material is greater than 0.5 eV.

By including the third material, the amount of the first material in the emissive layer is reduced. This reduces the probability of self-quenching for singlet and triplet excitons in the first material i.e. by non-radiative decay, and increases the probability for energy transfer to the second material.

Increasing the amount of the first material relative to the second material increases the probability of charge trapping occurring on the first material molecule sites. However, the amount of the first material relative to the third material is selected so as to reduce the probability of self-quenching occurring. The amount of the second material relative to the third material is also selected to increase the probability of energy transfer between the first material and the second material. The amount of the first and second material included in the emissive layer 4 may be varied and selected in order to increase device efficiency.

The organic light emitting device may comprise one or more additional layers in addition to the emissive layer. For example, the organic light emitting device of the invention may comprise a hole injection layer, a hole transport layer, an electron transport layer and/or an electron injection layer. The device according to an embodiment shown in FIG. 1 comprises a hole injection layer 2 provided overlying the anode 1 and a hole transport layer 3 provided overlying the hole injection layer 2. The emissive layer 4 is provided overlying the hole transport layer 3. An electron transport layer 5 is provided overlying the emissive layer 4, an electron injection layer 6 is provided overlying the electron transport layer 5, and the cathode 7 is provided overlying the electron injection layer 6. Optionally, the electron transport layer 4 also functions to remove unwanted inter-layer exciplex emission. Alternatively, an additional layer performing this function may optionally be included between the emissive layer 4 and the electron transport layer 5. Various other layers that are commonly used in OLED devices may optionally be included. The device is designed so that charge trapping occurs on the first material.

### First Material

A device according to an embodiment includes the first material which is an organic semiconductor compound as an energy donor (D) in the form of a closed-shell component. The first material has a spin singlet ground state. The first material may be a thermally-activated delayed fluorescent (TADF) material.

In an embodiment, the first material has a relatively low exchange energy. In an embodiment, the difference between the lowest singlet excitation energy level of the first material and the lowest triplet excitation energy level of the first material is less than 0.2 eV, in other words the following expression is satisfied:

|E_{S1}(D)−E_{T1}(D)|<0.2 eV (iii)

A lower exchange energy may reduce energy losses during operation and improve the overall power conversion efficiencies.

Preferably, the first material or energy donor (D) is a compound having an electron deficient component. More preferably, the first material or energy donor (D) is a compound having an electron deficient component and an electron rich component. In an embodiment, the electron deficient core may be one or more selected from the following moieties:

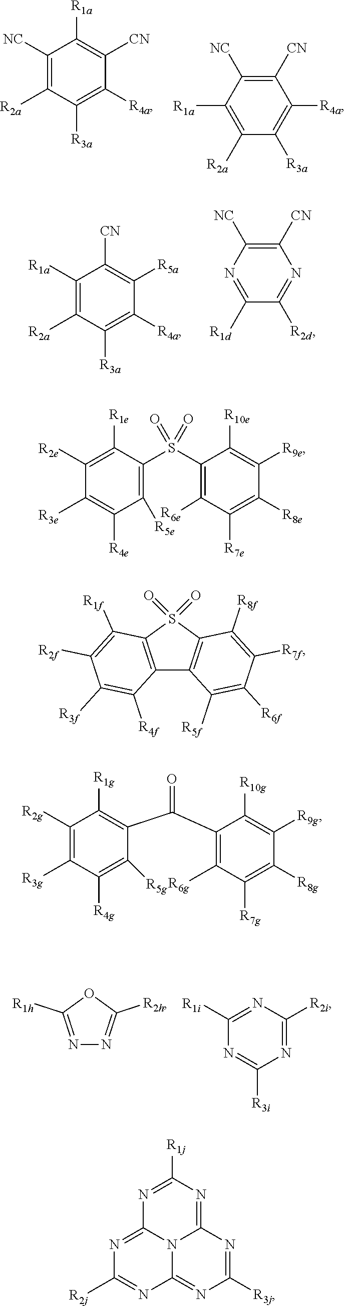

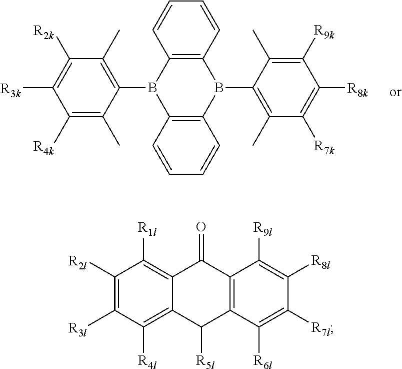

wherein R₁ₐ, R₂ₐ, R₃ₐ, R₄ₐ, R₅ₐ, R_{1d}, R_{2d}, R₁ₑ, R₂ₑ, R₃ₑ, R₄ₑ, R₅ₑ, R₆ₑ, R₇ₑ, R₈ₑ, R₉ₑ, R₁₀ₑ, R_{1f}, R_{2f}, R_{3f}, R_{4f}, R_{5f}, R_{6f}, R_{7f}, R_{8f}, R_{1g}, R_{2g}, R_{3g}, R_{4g}, R_{5g}, R_{6g}, R_{7g}, R_{8g}, R_{9g}, R_{10g}, R₁ₕ, R₂ₕ, R₁ᵢ, R₂ᵢ, R₃ᵢ, R₁ⱼ, R₂ⱼ, R₃ⱼ, R₂ₖ, R₃ₖ, R₄ₖ, R₇ₖ, R₉ₖ, R₁₀ₖ, R₁ₗ, R₂ₗ, R₃ₗ, R₄ₗ, R₅ₗ, R₆ₗ, R₇ₗ, R₈ₗ, R₉ₗ are independently selected from the groups consisting of one of the following electron rich components: H,

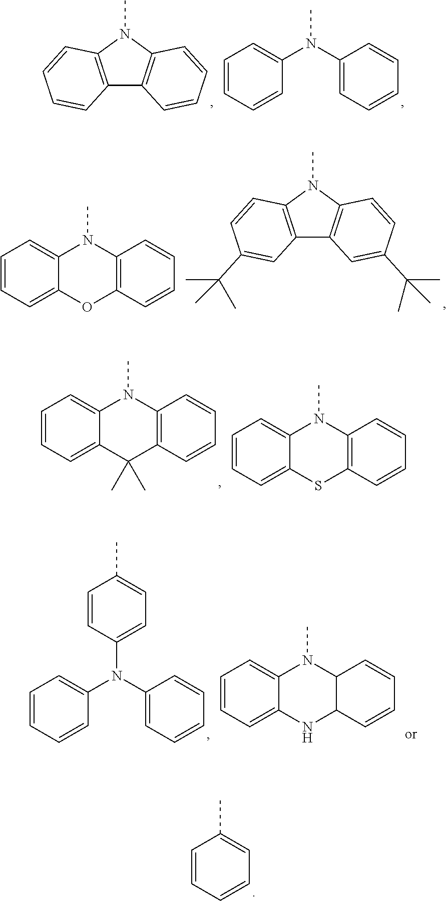

It is understood that the dashed line (_ _ _ _ _ _ ) indicates a point of attachment of the electron rich component to the electron deficient component. However, it will be appreciated that the electron rich component may be attached to the electron deficient component by a bond at a position other than the dashed line. For example, in the embodiment shown above, the N,N-diphenylaniline group is attached to the electron deficient component at the 4-position of one of the phenyl groups. However, in another embodiment the N,N-diphenylaniline group may be attached to the electron deficient component at the 2-position or the 3-position. In another embodiment, the group may be attached to the electron deficient component by 2 or more bonds. For example, the N,N-diphenylaniline group could be attached to the electron deficient component at the 2-position of one of the phenyl groups and the 2-position of another of the phenyl groups to one or more positions on the electron deficient component, such as in 10-phenyl-10H, 10′H-spiro[acridine-9,9′-anthracen]-10′-one (ACRSA).

In an embodiment, the electron deficient core of the first material is selected from the group consisting of:

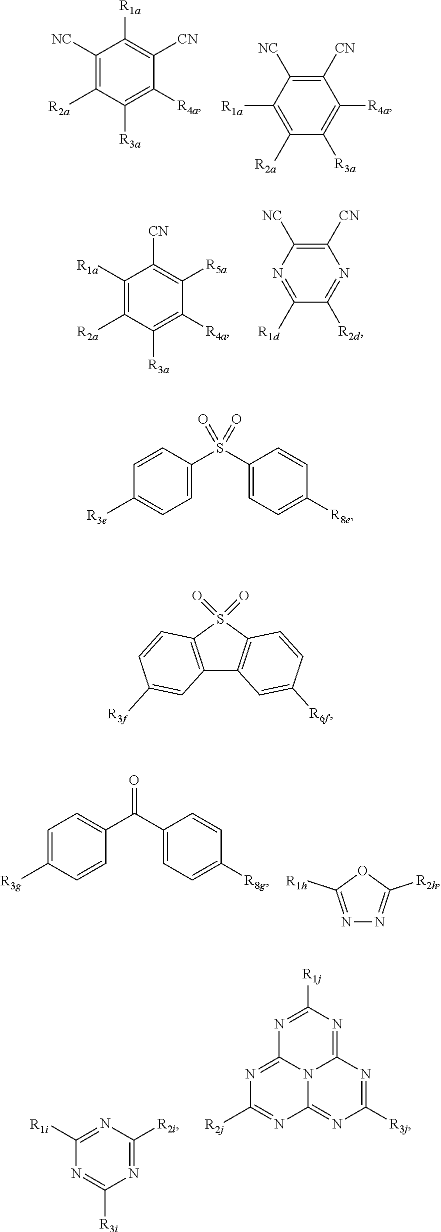

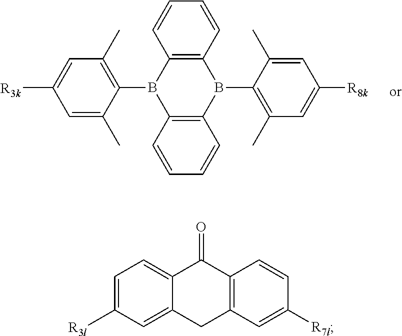

wherein R₁ₐ, R₂ₐ, R₃ₐ, R₄ₐ, R₅ₐ, R_{1d}, R_{2d}, R₃ₑ, R₄ₑ, R₅ₑ, R₈ₑ, R_{3f}, R_{6f}, R_{3g}, R_{8g}, R₁ₕ, R₂ₕ, R₁ᵢ, R₂ᵢ, R₃ᵢ, R₁ⱼ, R₂ⱼ, R₃ⱼ, R₃ₖ, R₈ₖ, R₃ₗ, R₇ₗ are electron rich groups and are independently selected from the groups consisting of H,

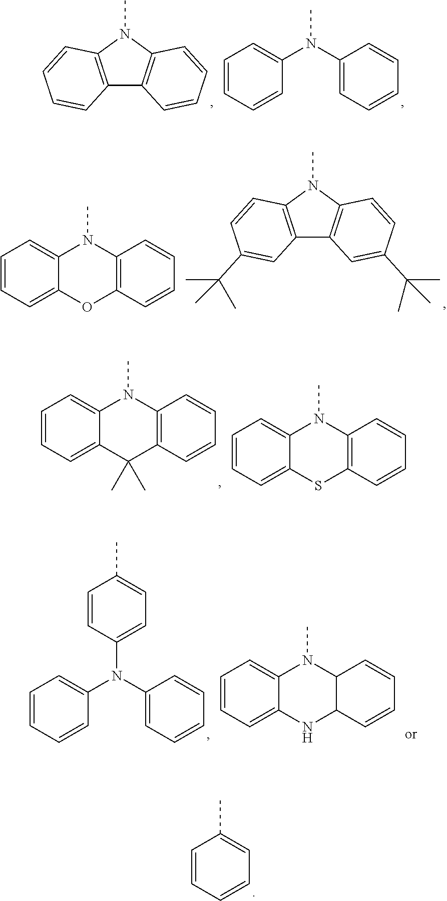

In an embodiment, the first material is a one or more selected from the group consisting of the following TADF emitters:

### Blue Emitters;

| | HOMO | LUMO | |
|---|---|---|---|
| | Energy | Energy | E(S1) |
| Chemical Name | (eV) | (eV) | (eV) |
| 2CzPN (1,2-Bis(carbazol-9-yl)-4,5-dicyanobenzene) | 6.2 | 3.5 | 2.6 |
| DMAC-DPS (10,10′-(4,4′-Sulfonylbis(4,1- | 5.9 | 2.9 | 2.6 |
| phenylene))bis(9,9-dimethyl-9,10-dihydroacridine) | | | |
| Cab-Ph-TRZ (9-(4-(4,6-Diphenyl-1,3,5-triazin-2- | 5.9 | 3.0 | 2.7 |
| yl)phenyl)-9H-carbazole) | | | |
| DMAC-BP (Bis[4-(9,9-dimethyl-9,10- | 5.8 | 3.1 | 2.5 |
| dihydroacridine)phenyl]methanone) | | | |
| PhCz2BP (Bis(4-(3,6-diphenyl-9H-carbazol-9- | 5.8 | 2.3 | 2.8 |
| yl)phenyl)methanone) | | | |
| Phen-TRZ (10-(4,6-Diphenyl-1,3,5-triazin-2-yl)-10H- | 6.5 | 3.1 | 2.5 |
| phenoxazine) | | | |
| BDBFCz-Trz(3,6-bis(dibenzo[b,d]furan-2-yl)-9-(4-(4,6- | 5.8 | 2.8 | 2.5 |
| diphenyl-1,3,5-triazin-2-yl)phenyl)-9H-carbazole) | | | |
| DMTDac (2,7-Bis(9,9-dimethylacridin-10(9H)-yl)-9,9- | 6.1 | 3.4 | 2.7 |
| dimethyl-9H-thioxanthene 10,10-dioxide) | | | |
| Cz-VPN (3,6-Dibenzoyl-4,5-Di(1-methyl-9-phenyl-9H- | 6.1 | 2.9 | 2.8 |
| carbazoyl)-2-ethynylbenzonitrile) | | | |
| CPC (2,6-di(9H-carbazol-9-yl)-4-phenylpyridine-3,5- | 6.3 | 3.5 | 2.6 |
| dicarbonitrile) | | | |
| DCzTrz (9,9′-(5-(4,6-diphenyl-1,3,5-triazin-2-yl)-1,3- | 5.9 | 2.9 | 2.8 |
| phenylene)bis(9H-carbazole)) | | | |
| DDCzTRZ (9,9′,9″,9′′′-((6-phenyl-1,3,5-triazine-2,4- | 6.0 | 2.9 | 2.8 |
| diyl)bis(benzene-5,3,1-triyl))tetrakis(9H-carbazole)) | | | |

### Green Emitters:

| | HOMO | LUMO | |
|---|---|---|---|
| | Energy | Energy | E(S1) |
| Chemical Name | (eV) | (eV) | (eV) |
| IDCzTrzDBF (12-(4-(4,6-diphenyl-1,3,5-triazin-2-yl)- | 5.9 | 3.3 | 2.9 |
| dibenzo[b,d]furan-3-yl)-5-phenyl-5,12-dihydroindolo[3,2- | | | |
| a]carbazole. | | | |
| TCzTrzDBF (9′-(4-(4,6-diphenyl-1,3,5-triazin-2-yl)- | 5.9 | 3.4 | 2.7 |
| dibenzo[b,d]furan-3-yl)-9,9″-diphenyl- 9H,9′H,9″H- | | | |
| 3,3′:6′,3″-tercarbazole) | | | |
| BCzTrzDBF (9-(4-(4,6-diphenyl-1,3,5-triazin-2-yl)- | 5.9 | 3.3 | 2.9 |
| dibenzo[b,d]furan-3-yl)-9′-phenyl-9H,9′H-3,3′- | | | |
| bicarbazole) | | | |
| DMAC-BP (bis[4-(9,9-dimethyl-9,10- | 5.8 | 3.1 | 2.5 |
| dihydroacridine)phenyl]methanone) | | | |
| TXO-PhCz (2-(9-phenyl-9H-carbazol-3-yl)-10,10-dioxide- | 5.8 | 3.6 | 2.4 |
| 9H-thioxanthen-9-one) | | | |
| CzDBA (5,10-bis(4-(9H-carbazol-9-yl)-2,6- | 5.9 | 3.5 | 2.4 |
| dimethylphenyl)-5,10-dihydroboranthrene) | | | |
| AcPmBPX (1,4-Bis(9,9-dimethylacridan-10-yl-pphenyl)- | 5.8 | 2.9 | 2.5 |
| 2,5-bis(ptolyl-methanoyl)benzene) | | | |
| PXZ-DPS (10-(4-(4-(10H-Phenoxazin-10- | 5.6 | 2.8 | |
| yl)phenylsulfonyl)phenyl)-10H-phenoxazine) | | | |

In a preferred embodiment, the first material or donor (D) is 4CzIPN (HOMO=5.8eV, LUMO=3.4eV) or CzDBA (HOMO=5.9, LUMO=3.5 eV).

In an embodiment, the first material is a compound having an electron deficient component, i.e. an acceptor moiety, with an electron rich component, i.e. a donor moiety. The HOMO is localised on the donor moiety, i.e. the electron rich component. The LUMO is localised on the acceptor moiety, i.e. the electron deficient component.

In an embodiment, the first material is contained in the emissive layer in an amount of from about 1% to about 99% by weight, in a further embodiment from about 2% to about 98% by weight. In an embodiment, the first material is contained in the emissive layer in an amount of from about 2% to about 70% by weight, in a further embodiment from about 2% to about 60% by weight, in a yet further embodiment about 2% to about 50% by weight. In an embodiment, the first material is contained in the emissive layer in an amount of from about 5% to about 70% by weight, in a further embodiment from about 5% to about 60% by weight, in a yet further embodiment about 5% to about 50% by weight.

Given a second material, the first material may be selected to satisfy expression (i) above, namely E_{S1}(D)>E_{D1}(A), and E_{T1}(D)>E_{D1}(A). Given a specific second material, a suitable first material may be selected to satisfy energy transfer to the radical.

### Second Material

A device according to an embodiment includes the second material which is an organic semiconductor compound as an energy acceptor (A) in the form of an open-shell component having a spin doublet ground state. The first material and second material are different organic semiconductor compounds.

In an embodiment, the second material is a stable organic radical in the ground state. In an embodiment, the stable organic radical is a radical that decays with an exponential lifetime of over about 1 hr, in a further embodiment over about 1.5 hr, in a yet further embodiment over about 2 hr in the dark and in the absence of oxygen. A stable organic radical thereby differs from transient radical which has a shorter lifetime, normally on the order of milliseconds because it is highly reactive e.g. to a hydrogen abstraction, dimerization and/or cyclisation reaction.

The radical's inherent stability can be measured by monitoring its absorption profile with time using a UV-Vis spectrometer (e.g. solution study: for 100 μM solution in chloroform; film study: for radical doped at 2-10% wt. in host of suitable first or third material as described above). In an embodiment, the stable organic radical is a compound having an exponential lifetime of over 1 hr when measured by monitoring its absorption profile with time using a UV-Vis spectrometer in a solution study for 100 μM in chloroform. In an embodiment, the stable organic radical is a compound having an exponential lifetime of over 1 hr when measured by monitoring its absorption profile with time in a film study wherein the radical is doped at 2-10 wt % in host of suitable first material or third material as described above. For example, the stable organic radical is an organic radical having a lifetime of over 1 hr when measured by monitoring its absorption profile with time in a film study where the radical is doped at 5 wt % in 4CzIPN and/or in a film study where the radical is doped at 3 wt % in CBP.

In an embodiment, the organic radical exhibits sufficient thermal stability that it can withstand a vacuum deposition process. In an embodiment, the organic radical exhibits about 5% or less decomposition as measured by thermogravimetric analysis at the temperature selected for deposition, in a further embodiment about 4% or less, in a yet further embodiment about 3% or less, or in a yet further embodiment about 2% of less. In one embodiment, the thermal decomposition temperature of the second material is higher than the evaporation temperature of the second material under vacuum. In one embodiment, the thermal decomposition temperature of the second material is 500 K or higher, 525 K or higher, 550 K or higher, 575 K or higher, 600 K or higher, 625 K or higher, 650 K of higher, 675 K or higher, 700 K or higher, 725 K or higher, or 750 K or higher, provided that the thermal decomposition temperature is higher than the evaporation temperature of the second material under vacuum. In an embodiment, the evaporation temperature of the second material is 700 K or lower, 675 K or lower, 650 K or lower, 625 K or lower, 600 K or lower, 575 K or lower, 550 K or lower, 525 K or lower, 475 K or lower, or 473 K or lower, provided that the evaporation temperature of the second material under vacuum is lower than the thermal decomposition temperature of the second material. In one embodiment, the thermal decomposition temperature is higher than the evaporation temperature of the second material under vacuum by at least 50 K, at least 75 K, at least 100 K, at least 125 K, at least 150 K, at least 175 K or at least 200 K. For example, TTM-3PCZ and TTM-3NCz have evaporation temperatures under vacuum of less than 473 K, and thermal decomposition temperatures of 635 K and 640 K, respectively.

In an embodiment, the organic radical has sufficient redox stability so that it can withstand interaction with negative (electron) and positive (hole) charges in a device. To this end, it is preferable that the cyclic voltammetry trace for a radical does not exhibit hysteresis upon repeated cycles.

In an embodiment, the organic radical has sufficient photostability so that it does not decompose upon formation of excited states during device operation. In an embodiment, the radical displays exponential decay lifetimes of over about 1 hr following photoexcitation with a laser of higher energy than the lowest energy absorption band. These measurements can be undertaken in solution (e.g. concentration 100 μM in chloroform), in the absence of oxygen, with 355 nm CW laser, power density>100 kW/cm².

The second material is a compound that emits fluorescent light when transitioning from a lowest spin doublet excitation energy level to a ground energy level. The second material is a luminescent material. In an embodiment, the second material exhibits photoluminescence quantum efficiency (PLQE) of greater than 5%, in a further embodiment greater than about 10%. A higher luminescence for the second material results in improved emission efficiency for the device. In an embodiment, the absorption extinction coefficient of the second material for the lowest energy transition is greater than about 500 M⁻¹cm⁻¹, in a further embodiment greater than about 1000 M⁻¹cm⁻¹, in a yet further embodiment greater than about 1500 M⁻¹cm⁻¹, in a yet further embodiment greater than about 2000 M⁻¹cm⁻¹.

In an embodiment, the second material or acceptor (A) is a stabilised organic radical having a stabilised organic radical component. Preferably, the radical component is an electron acceptor moiety. In an embodiment, the second material has an electron donor moiety. Preferably, the second material is a compound having a donor moiety and a stabilised organic radical component. The stabilised organic radical core/acceptor moiety may be one or more selected from the group consisting of:

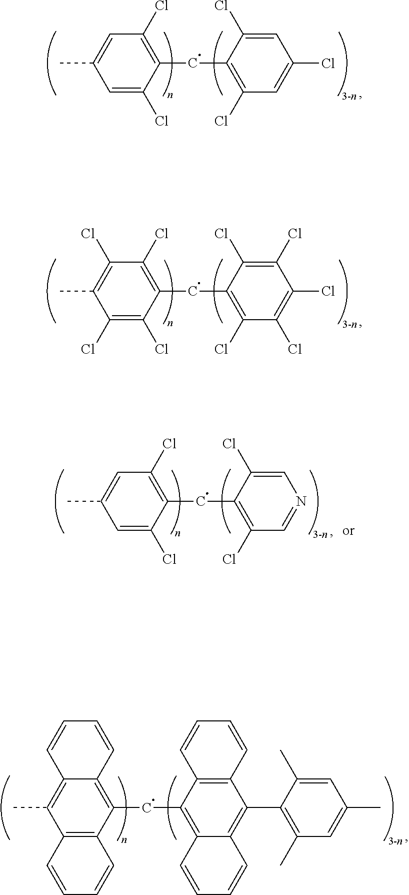

wherein n=1, 2 or 3 and _ _ _ _ _ _ indicates the point attachment to the donor moiety.

The electron donor moiety is any one selected from the group consisting of: _ _ _ _ _ _ H, _ _ _ _ _ _ Cl,

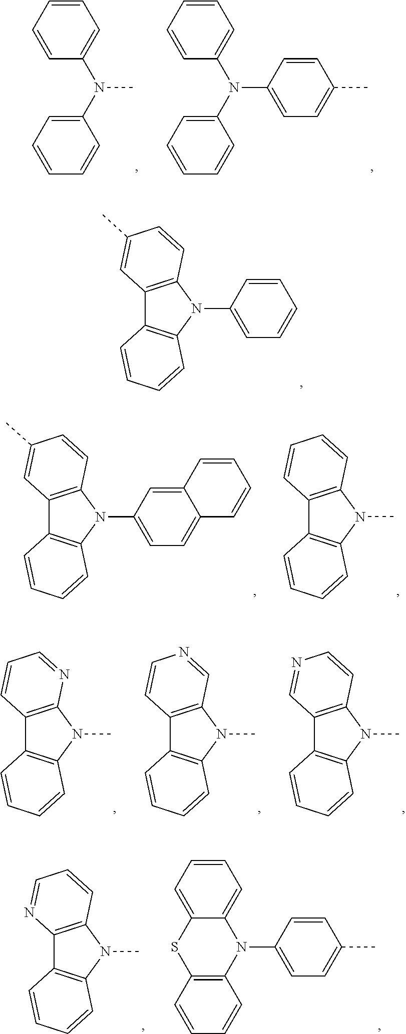

wherein _ _ _ _ _ _ indicates the point of attachment to the acceptor moiety.

It is understood that the dashed line (_ _ _ _ _ _ ) indicates a point of attachment of the groups to the radical component. However, it will be appreciated that the group may be attached to the radical component by a bond at a position other than the dashed line. For example, in the embodiment shown above, the N,N-diphenylaniline group is attached to the radical component at the 4-position of one of the phenyl groups. However, in another embodiment the N,N-diphenylaniline group may be attached to the radical component at the 2-position or the 3-position. In another embodiment, the group may be attached to core by 2 or more bonds. For example, the N,N-diphenylaniline group could be attached to the radical component at the 2-position of one of the phenyl groups and the 2-position of another of the phenyl groups to one or more positions on the radical component.

Examples of organic semiconductor compounds suitable to be used as the second material include those based on the tris(2,4,6-trichlorophenyl)methyl (TTM) radical component. For example, the second material may be based on the TTM radical component in which one of 3-substituted-9-(naphthalen-2-yl)-9H-carbazole (3NCz), 3-substituted-9-phenyl-9H-carbazole (3PCz), triphenylamine (TPA) or pyrido[2,3-b]indole (αPylD) is incorporated. In a preferred embodiment, the second material is selected from the group consisting of TTM-1Cz, TTM-3NCz, TTM-3PCz, TTM-TPA, TTM-PPTA and TTM-αPylD.:

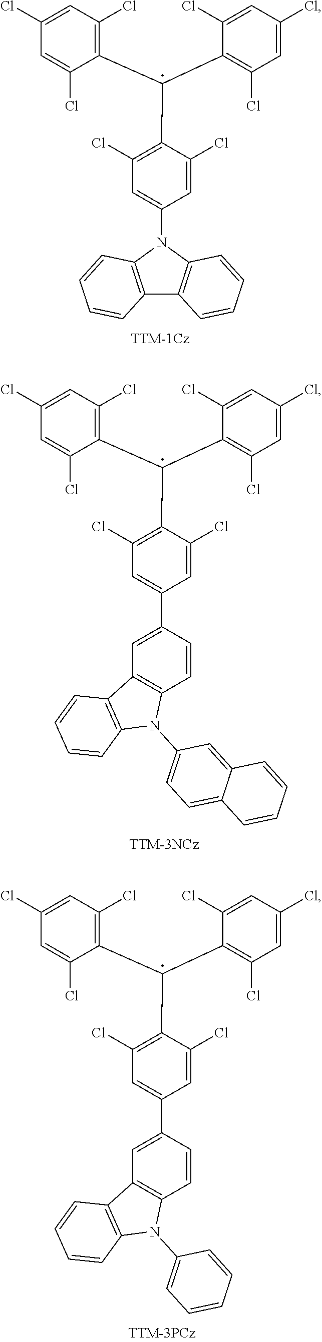

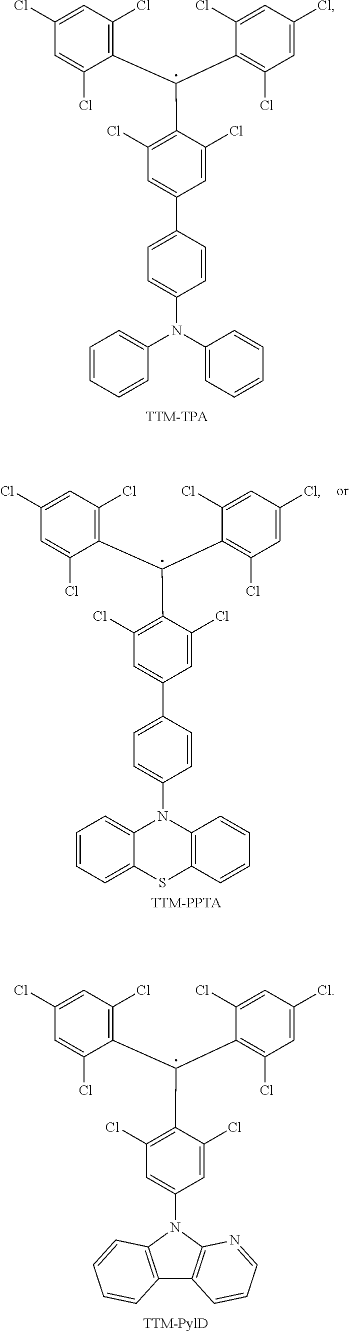

These materials comprise a ‘donor’ moiety (e.g. 3NCz/3PCz) and an ‘acceptor’ TTM radical moiety. This leads to strong charge-transfer character for the first excited state, with substantial spatial separation and little overlap for the donor (e.g. 3NCz/3PCz)-centred HOMO and TTM-centred SOMO. Various properties of TTM-3NCz and TTM-3PCz are described in Ai, X., Evans, E. W., Dong, S. et al. Efficient radical-based light-emitting diodes with doublet emission, Nature 563, 536-540 (2018) doi:10.1038/s41586-018-0695-9, the entire contents of which, including the extended data and supplementary information, are incorporated herein by reference.

In an embodiment, the second material is a one or more selected from the group consisting of the following:

| Chemical | HOMO | SOMO Energy (eV) | E(D1) |
|---|---|---|---|
| Name | Energy (eV) | for reduction | (eV) |
| TTM-3PCz | 5.5-6 | 3.7 | 1.78 |
| TTM-3NCz | 5.5-6 | 3.7 | 1.75 |
| TTM-TPA | 5.3-5.8 | 3.7 | 1.59 |
| TTM- αPyID | 5.5-6 | 3.7 | 1.97 |

In an embodiment, the second material is a compound having an electron deficient component, i.e. an acceptor moiety, with an electron rich component, i.e. a donor moiety. The HOMO is localised on the donor moiety, i.e. the electron rich group. The SOMO is localised on the acceptor moiety, i.e. the electron deficient radical core.

In an embodiment, the second material may be contained in the emissive layer in an amount of from about 1% to about 10% by weight, in a further embodiment from about 1% to about 6% by weight, in a yet further embodiment from about 1% to about 5% by weight. In an embodiment, the second material is contained in the emissive layer in an amount of from about 2% to about 10% by weight, in a further embodiment from about 2% to about 6% by weight, in a yet further embodiment about 2% to about 5% by weight.

### Third Material

In some embodiments, the device includes a third material which is a different organic semiconductor and which acts as a host material into which the first material and second material are doped. The third material may be selected from any one or more standard fluorescent or phosphorescent host materials for use in an organic light emitting device.

In one embodiment, the emissive layer comprises the third material that is doped with the first material with a concentration of greater than about 4% by weight, and in yet another embodiment with a concentration of greater than or equal to about 5% by weight, in a further embodiment greater than about 20% by weight. In an embodiment, the emissive layer comprises the third material doped with the first material with a concentration of less than about 70% by weight, in a further embodiment less than about 60% by weight, in a yet further embodiment less than or equal to about 50% by weight. In an embodiment, the emissive layer comprises the third material doped with the first material with a concentration of less than about 60% by weight and greater than about 4% by weight. In an embodiment, the emissive layer comprises the third material doped with the first material with a concentration of less than or equal to about 50% by weight and greater than or equal to about 5% by weight.

In another embodiment, the emissive layer comprises the third material that is doped with the second material with a concentration of less than about 10% by weight, in a further embodiment less than about 6% by weight, in a yet further embodiment less than or equal to about 5% by weight. In an embodiment, the emissive layer comprises the third material doped with the second material with a concentration of greater than about 1% by weight, in a further embodiment greater or equal to about 2% by weight. In an embodiment, the emissive layer comprises the third material doped with the second material with a concentration of less than about 6% by weight and greater than about 1% by weight. In a further embodiment, the emissive layer comprises the third material doped with the second material with a concentration of less than or equal to about 5% by weight and greater than or equal to about 2% by weight.

In an embodiment, the emissive layer comprises the third material and the third material is doped with the first material with a concentration of less than about 60% by weight and greater than about 4% by weight and is doped with the second material with a concentration of less than about 6% by weight and greater than about 1% by weight, where an amount of the first organic semiconductor compound in the emissive layer is greater than an amount of the second organic semiconductor compound in the emissive layer. In a further embodiment, the emissive layer comprises the third material and the third material is doped with the first material with a concentration less than or equal to about 50% by weight and greater than or equal to about 5% by weight and is doped with the second material with a concentration of less than or equal to about 5% by weight and greater than or equal to about 2% by weight, where an amount of the first organic semiconductor compound in the emissive layer is greater than an amount of the second organic semiconductor compound in the emissive layer. In an embodiment, the third material is doped with the second material with a concentration of less than or equal to 10% by weight and doped with the first material with a concentration of greater than or equal to 2% by weight. In a yet further embodiment, the third material is doped with the second material with a concentration of less than or equal to 5% by weight and doped with the first material with a concentration of greater than or equal to 5% by weight and less than or equal to 50% by weight.

In one embodiment, the third material is one or more standard phosphorescent host materials for closed-shell (non-radical) emitters selected from the group consisting of:

TPBi, OXD-7, m-MTDATA, TCTA, TmPyPB, T2T, TAPC, TAZ, TPD, PPT, CzSi, TCP, Zn(BTZ)2, CBP, CDBP, mCBP, UGH-2, BCzPh, MCP, PYD-2Cz, 26DCzPPy, 35DCzPPy, 3TPYMB, BAlq, BCPO, BTB, Tris-PCz, and BCBP. In another embodiment, the third material is one or more standard fluorescent host materials for closed-shell (non-radical) emitters selected from the group consisting of TSPO1, TPBi (HOMO energy 6.2-6.7 eV, LUMO energy 2.8 eV), Alq3, CBP, mCP, PPT, dPVBi, MADN, DPEPO, CzSi, BCPO, Tris-PCz, PYD-2Cz, PXZ-DPS, mCPSOB, mCBP, CDMP, and BCzPh. The third material may be a single host material or a mixture of one or more host materials. In a preferred embodiment, the third material is CBP (4,4′-Bis(N-carbazolyl)-1,1′-biphenyl) (HOMO energy 6 eV, LUMO energy 2.9 eV).

### Anode

Various materials are known for use as an anode in an organic light emitting device, including various metals, alloys and conducting materials, including transparent conducting oxides. The anode may be formed from one of these materials. For example, the anode may comprise a transparent conducting material such as indium tin oxide (ITO) or zinc oxide (ZnO). Preferably, the anode has a transmittance of more than 10%, such that light is emitted from the device through the anode. The thickness of the anode may be generally selected from a range of from about 100 to about 1000 nm for example.

### Cathode

Various materials are known for use as a cathode in an organic light emitting device, including various metals, alloys and conducting materials. Specific examples include aluminium, silver and gold.

The cathode preferably has thickness selected from a range of from 10 nm to 1 μm, and preferably from 50 to 200 nm. In a preferred embodiment, the cathode is aluminium. In another preferred embodiment, the cathode is about 100 nm thick. In a further preferred embodiment, the cathode is aluminium and 100 nm thick.

In the described examples, the anode is formed from an electrically conductive transparent material, however the cathode may additionally or alternatively be formed with an electrically conductive transparent material.

### Hole Injection Layer

An organic light emitting device according to an embodiment may include a hole injection layer 2 provided between the anode 1 and the emissive layer 4 or the hole transport layer 3. Inclusion of the hole injection layer 2 acts to enhance the device efficiency. Various materials are known for use as a hole injection layer in an organic light emitting device. The hole injection layer may comprise one or more of a molybdenum oxide, PEDOT:PSS, F4TCNQ, titanyl phthalocyanine, TcTA, dPVBi, or TCP. Particularly, molybdenum trioxide may be used.

### Electron Injection Layer

An organic light emitting device according to an embodiment may include an electron injection layer 6 provided between the cathode 6 and the electron transporting layer 5. Inclusion of the electron injection layer 6 acts to enhance the device efficiency by lowering the energetic barrier to charge injection.

Various materials are known for use as an electron injection layer in an organic light emitting device. In a preferred embodiment, the electron injection layer may comprise one or more of TSPO1, BCP, TPBi, Alq3, OXD-7, BPhen, TAZ, PPDN, lithium fluoride (LiF) or calcium (Ca). Preferably, the electron injection layer is formed of LiF. The electron injection layer may be from about 0.1 nm to about 5 nm thick, preferably from about 0.2 nm to about 2 nm thick, more preferably from about 0.5 nm to about 1 nm thick, even more preferably from about 0.6 nm to about 0.9 nm thick, and most preferably about 0.8 nm thick. In a preferred embodiment, the electron injection layer is 0.8 nm thick and is LiF.

### Hole Transport Layer

An organic light emitting device according to an embodiment may include a hole transporting layer 3. Various materials are known for use as hole transporting material in an organic light emitting device. The hole transporting material may be an organic material. For example, the hole transporting material may be HATCN, NPB, mCP, TPD, TCP, MADN, CzSi, Tris-PCz, TTPA, or TAPC. In an embodiment, the hole transporting material is 1,1-Bis[(di-4-tolylamino)phenyl]cyclohexane (TAPC) (HOMO energy 5.5 eV, LUMO energy 2.1 eV).The hole transporting layer may be from about 1 nm to about 200 nm thick, from about 5 nm to about 100 nm thick, from about 10 nm to about 50 nm thick, from about 20 nm to about 40 nm thick, or from about 40 nm thick. In an embodiment, the hole transporting layer is 40 nm thick and is TAPC. The hole transporting layer may be provided adjacent the anode 1 or the hole injection layer 2 and the emissive layer 4.

In an embodiment, the HOMO of the hole transporting material is lower energy than, i.e. has a larger magnitude than the HOMO of the first material. In this embodiment, the difference between the HOMO of the hole transporting material and the HOMO the first material is about 0.1 to 1.0 eV, about 0.3 to 0.7 eV, or about 0.3 to 0.4 eV. In another embodiment, the HOMO of the hole transporting material is about the same in energy as the HOMO of the first material. In an embodiment, the difference between the HOMO of the hole transporting material and the HOMO of the first material is less than about 0.1 eV.

### Electron Transport Layer

An organic light emitting device according to an embodiment may include an electron transporting layer 5. Various materials are known for use as an electron transporting material in an organic light emitting device. The electron transporting material may be an organic material. In an embodiment, the electron transporting material is 4,6-Bis(3,5-di(pyridin-3-yl)phenyl)-2-methylpyrimidine (B3PYMPM) (HOMO energy 7.0 eV, LUMO energy 3.4 eV). B3PYMPM additionally acts to remove unwanted green inter-layer exciplex emission. The material of the electron transport layer may be selected for electron injection into the LUMO of the first material, for example the 4CzIPN LUMO. The electron transporting layer may be from about 1 nm to about 200 nm thick, from about 5 nm to about 100 nm thick, from about 20 nm to about 80 nm thick, from about 40 nm to about 70 nm thick, or about 60 nm thick. In an embodiment, the hole transporting layer is 60 nm thick and is B3PYMPM. In any case, the electron transporting layer may be provided adjacent the cathode 1 or the electron injection layer 6 and the emissive layer 4. In an embodiment, the electron transporting material is 3TPYMB, Alq3, B2PymPm, B3PymPm, B3PyPB, B4PymPm, B4PyPPm, BAlq, BCP, Bebq2, Bepp2, BPhen, BTB, DPEPO, DPPS, OXD-7, PPT, T2T, TAZ, TmPyPB, TPBi, TSPO1, UGH-2, ZADN or ZN(BTZ)2.

In an embodiment, the LUMO of the electron transporting material is higher energy than, i.e. has a smaller magnitude than, the LUMO of the first material. In this embodiment, the difference between the LUMO of the electron transporting material and the LUMO of the first material is about 0.1 eV to 0.5 eV, about 0.2 eV to 0.4 eV or about 0.1 eV to 0.2 eV. In another embodiment, the LUMO of the electron transporting material is about the same in energy as the LUMO of the first material i.e. the difference between the LUMO of the electron transporting material and the LUMO of the first material is less than about 0.1 eV.

In an embodiment, the LUMO of the material forming the layer adjacent to the emissive layer and between the emissive layer and the cathode is higher energy than, i.e. has a smaller magnitude than, the LUMO of the first material. In this embodiment, the difference between the LUMO of this material and the LUMO of the first material is about 0.1 eV to 0.5 eV, about 0.2 eV to 0.4 eV or about 0.1 eV to 0.2 eV. In another embodiment, the LUMO of this material is about the same in energy as the LUMO of the first material i.e. the difference between the LUMO of this material and the LUMO of the first material is less than about 0.1 eV.

### Emissive Layer

Various specific examples of the combination of materials included in the emissive layer will now be described:

| First | | | Second | | Third |
|---|---|---|---|---|---|
| material | ES₁ | ET₁ | material | ED₁ | material |
| 4CzIPN | 2.42 eV | 2.38 eV | TTM-3PCz | 1.78 eV | |
| 4CzIPN | 2.42 eV | 2.38 eV | TTM-3PCz | 1.78 eV | CBP |
| 4CzIPN | 2.42 eV | 2.38 eV | TTM-3NCz | 1.75 eV | |
| 4CzIPN | 2.42 eV | 2.38 eV | TTM-3NCz | 1.75 eV | CBP |
| 4CzIPN | 2.42 eV | 2.38 eV | TTM-αPyID | 1.97 eV | |
| 4CzIPN | 2.42 eV | 2.38 eV | TTM-αPyID | 1.97 eV | CBP |
| 4CzIPN | 2.42 eV | 2.38 eV | TTM-TPA | 1.59 eV | |
| 4CzIPN | 2.42 eV | 2.38 eV | TTM-TPA | 1.59 eV | CBP |
| CzDBA | 2.63 eV | 2.60 eV | TTM-3PCz | 1.78 eV | |

Various specific examples of the composition of the emissive layer will now be described:

| Example | First material | Second material | Third material |
|---|---|---|---|
| 1 | 25% 4CzIPN | 3% TTM-3PCz | 72% CBP |
| 2 | 25% 4CzIPN | 4% TTM-αPyID | 70% CBP |
| 3 | 5% 4CzIPN | 5% TTM-3NCz | 90% CBP |
| 4 | 95% 4CzIPN | 5% TTM-3NCz | |
| 5 | 97% CzDBA | 3% TTM-3PCz | |

Various examples of specific devices of the first embodiment will now be described in the following section.

### Example 1

A device in accordance with an embodiment will now be described. The device is a deep red-near infrared doublet emitter (714 nm). The device may be suitable for display technologies.

The anode comprises ITO. A second layer comprising MoO₃ is formed overlying the anode. The second layer is 5 nm thick. The second layer is a hole injection layer.

A hole transport layer comprising 1-Bis[4-[N,N-di(4-tolyl)amino]phenyl]cyclohexane (TAPC) is formed overlying the second layer. The hole transport layer is a 40 nm thick layer.

An emissive layer is formed overlying the hole transport layer. The emissive layer is 30 nm. The emissive layer comprises a first material, 4CzIPN, and a second material, TTM-3PCz, doped into a third material, CBP. The emissive layer comprises 25 wt % 4CzIPN and 3 wt % TTM-3PCz doped into CBP. A lowest spin singlet excitation energy of the first material is 2.42 eV. A lowest spin triplet excitation energy of the first material is 2.38 eV. A lowest spin doublet excitation energy of the second material is 1.78 eV.

An electron transport layer comprising 4,6-Bis(3,5-di(pyridin-3-yl)phenyl)-2-methylpyrimidine (B3PYMPM) is formed overlying the light-emitting layer. The electron transport layer is 60 nm.

A sixth layer comprising LiF is formed overlying the fifth layer. The sixth layer is 0.8 nm. The sixth layer is an electron injection layer.

The cathode is formed overlying the sixth layer, and comprises Al. The cathode is formed in a 100 nm thick layer.

FIG. 5 shows the electroluminescence current density (EQE) device characteristics for the device of Example 1 (filled squares). FIG. 5 shows a plot of the external quantum efficiency (EQE) against the current density for the device. A maximum EQE value of 16% is obtained at 1 μA/cm². An EQE value of 13% is found at 1 mA/cm². The ratio of the EQE value at 1 mA/cm² to the maximum EQE value was 0.81. Thus a high electroluminescent efficiency may be achieved, with reduced roll-off at high current densities.

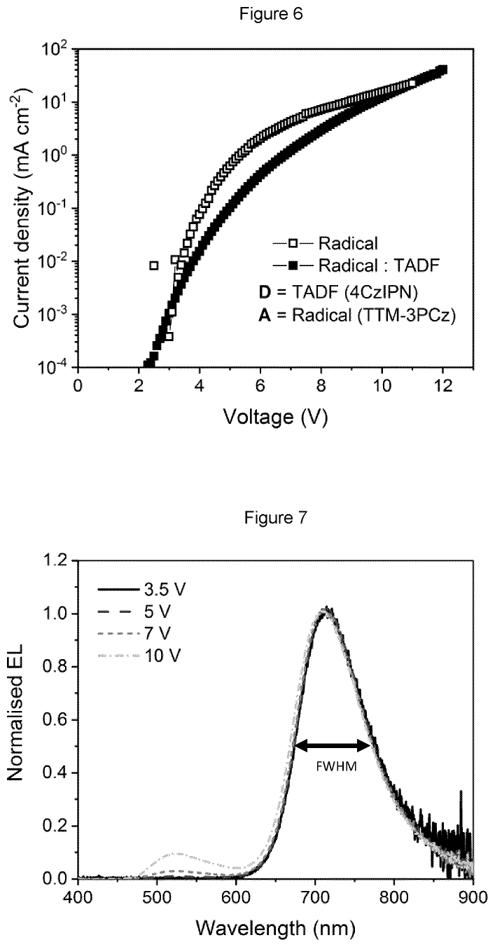

FIG. 6 plots the diode characteristic of the current density against voltage for the Example 1 device (filled squares).

FIG. 7 shows normalised electroluminescence (EL) profiles for the same device. The electroluminescence peak from the TTM-3PCz appears at 714 nm. The electroluminescence peak at 714 nm is slightly red shifted with increasing voltage as shown, from 3.5 V to 10 V (710 nm). An increasing 4CzIPN contribution appears at 520 nm with increasing voltage however. There is therefore an increasing 4CzIPN contribution and decreasing TTM-3PCz contribution to the total device colour with increasing voltage. The contribution from the first material to the total device colour can be removed by increasing the efficiency of energy transfer from the first material to the second material. Sub-microsecond luminescence lifetimes may be achieved.

### Comparative Example 1

A device according to a first comparative example will now be described. In this device, the emissive layer comprises a radical TTM-3PCz and a further material, CBP.

The anode comprises ITO. A second layer comprising MoO₃ is formed overlying the anode. The second layer is 3 nm.

A hole transport layer comprising 1-Bis[4-[N,N-di(4-tolyl)amino]phenyl]cyclohexane (TAPC) formed in a 25 nm thick layer overlying the second layer.

An emissive layer is formed overlying the hole transport layer. The emissive layer is 30 nm. The emissive layer comprises TTM-3PCz, doped into a further material, CBP. The emissive layer comprises 3 wt % TTM-3PCz doped into CBP. A lowest spin singlet excitation energy of the further material is 3.32 eV. A lowest spin triplet excitation energy of the further material is 2.49 eV. A lowest spin doublet excitation energy of the radical is 1.78 eV.

A fifth layer comprising 4,6-Bis(3,5-di(pyridin-3-yl)phenyl)-2-methylpyrimidine (B3PYMPM) is formed overlying the light-emitting layer. This layer is included to remove unwanted green emission (formed by exciplex between CBP host and electron transport layer). The layer is 10 nm.

An electron transport layer comprising 2,4,6-tris[m-(diphenylphosphinoyl)phenyl]-1,3,5-triazine (PO-T2T, HOMO energy 7.0 eV, LUMO energy 3.4 eV) is formed overlying the fifth layer. The electron transport layer is 70 nm thick.

A seventh layer comprising LiF is formed overlying the electron transport layer. The seventh layer is 0.8 nm.

The cathode is formed overlying the seventh layer, and comprises Al formed in a 100 nm thick layer.

FIG. 5 shows the electroluminescence current density EQE device characteristics for the device of Comparative Example 1, in the data represented by open squares. FIG. 5 shows a plot of the external quantum efficiency (EQE) against the current density for the device. A maximum EQE value of 17% is obtained. An EQE value of 9% is found at 1 mA/cm². The ratio of the EQE value at 1 mA/cm² to the maximum EQE value was 0.56. The electroluminescence peak appears at 703 nm.

### Example 2

A device according to an embodiment will now be described. A device according to Example 2 was prepared as follows.

The anode comprises ITO. A second layer comprising MoO₃ is formed overlying the anode. The second layer is 5 nm. The second layer is a hole injection layer.

A hole transport layer comprising 1-Bis[4-[N,N-di(4-tolyl)amino]phenyl]cyclohexane (TAPC) formed overlying the second layer. The hole transport layer is a 40 nm thick layer.

An emissive layer is formed overlying the hole transport layer. The emissive layer is 30 nm. The emissive layer comprises a first material, 4CzIPN, and a second material, TTM-αPylD, doped into a third material, 4,4-bis(carbazol-9-yl)biphenyl (CBP). The emissive layer comprises 25 wt % 4CzIPN and 4 wt % TTM-αPylD doped into CBP. A lowest spin singlet excitation energy of the first material is 2.42 eV. A lowest spin triplet excitation energy of the first material is 2.38 eV. A lowest spin doublet excitation energy of the second material is 1.97 eV.

An electron transport layer comprising 4,6-Bis(3,5-di(pyridin-3-yl)phenyl)-2-methylpyrimidine (B3PYMPM) is formed overlying the light-emitting layer. The electron transport layer is 60 nm.

A sixth layer comprising LiF is formed overlying the electron transport layer. The sixth layer is 0.8 nm.

The cathode is formed overlying the sixth layer, and comprises Al. The cathode is formed in a 100 nm thick layer.

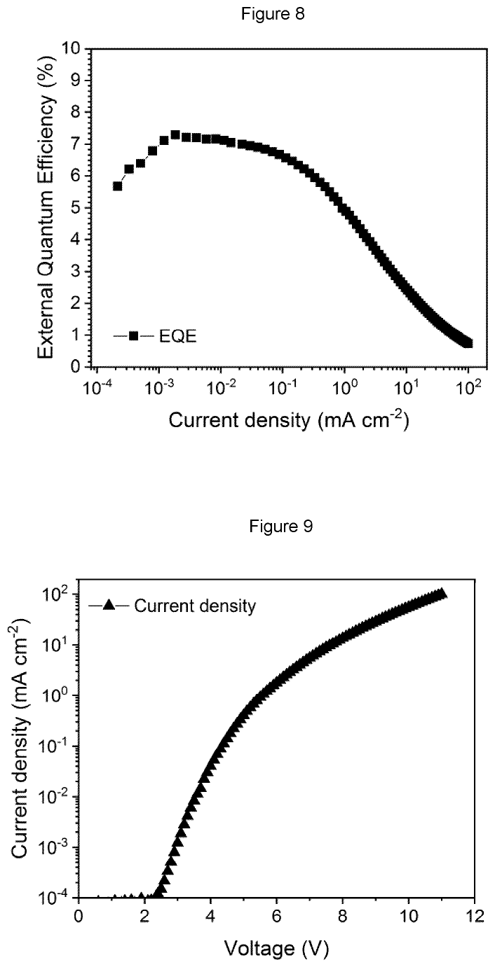

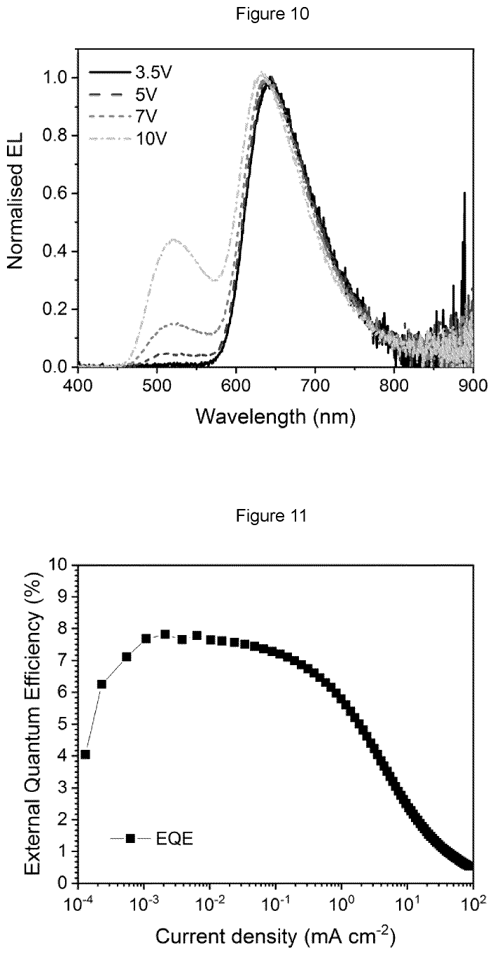

FIG. 8 shows the electroluminescence current density (EQE) device characteristics for the device of Example 2. FIG. 8 shows a plot of the EQE against the current density for the device. A maximum EQE of 7% is found at 1 μA/cm², and an EQE of 5% is found at 1 mA/cm². The ratio of the EQE value at 1 mA/cm² to the maximum EQE value was 0.71. The EQE at 1 mA/cm² is greater than 0.65 of the maximum EQE. The current density against voltage diode characteristic of the device is shown in FIG. 9. Similar to FIG. 7, the electroluminescence profiles show increasing 4CzIPN contribution at 520 nm and decreasing TTM-αPylD contribution at 639 nm to the total device colour with increasing voltage (FIG. 10).

### Example 3

A device according to an embodiment will now be described. The device according to Example 3 was prepared in the same way as a device according to Example 1, except the composition of the emissive layer was changed.

The emissive layer is 30 nm. The emissive layer comprises a first material, 4CzIPN, and a second material, TTM-3NCz, doped into a third material, CBP. The emissive layer comprises 5 wt % 4CzIPN and 5 wt % TTM-3NCz doped into CBP. A lowest spin singlet excitation energy of the first material is 2.42 eV. A lowest spin triplet excitation energy of the first material is 2.38 eV. A lowest spin doublet excitation energy of the second material is 1.75 eV.

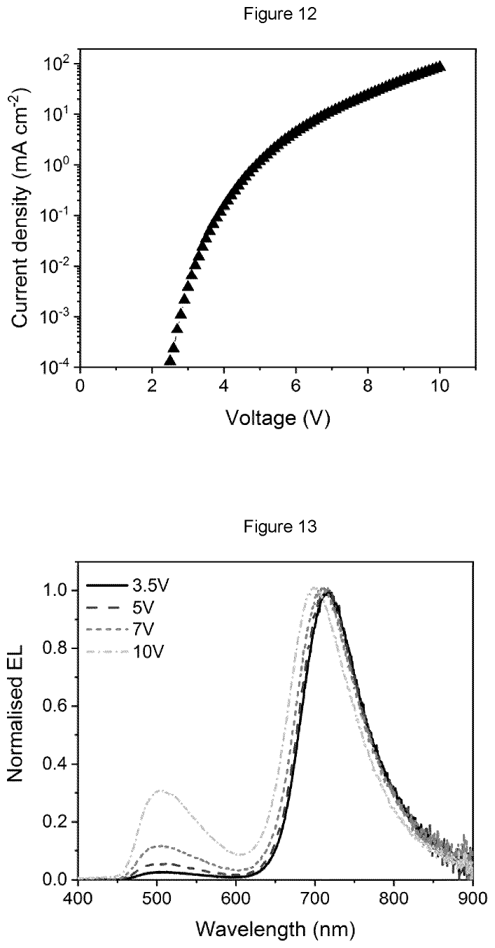

FIG. 11 shows the electroluminescence current density (EQE) device characteristics for the device of Example 3. FIG. 11 shows a plot of the EQE against the current density for the device. A maximum EQE value of 8% is obtained at 1 μA/cm². An EQE value of 6% is found at 1 mA/cm². The ratio of the EQE value at 1 mA/cm² to the maximum EQE value was 0.75. Thus a high electroluminescent efficiency may be achieved, with reduced roll-off at high current densities. The current density against voltage diode characteristic of the device is shown in FIG. 12.

Similar to FIGS. 7 and 10, the electroluminescence profiles show increasing 4CzIPN contribution at 520 nm and decreasing TTM-3NCz contribution at 716 nm to the total device colour with increasing voltage (FIG. 13).

### Example 4

A device according to an embodiment will now be described. The device according to Example 4 was prepared in the same way as a device according to Example 1, except the composition of the emissive layer was changed.

The emissive layer is 30 nm. The emissive layer comprises a first material, 4CzIPN, and a second material, TTM-3NCz. The emissive layer comprises 95 wt % 4CzIPN and 5 wt % TTM-3NCz. A lowest spin singlet excitation energy of the first material is 2.42 eV. A lowest spin triplet excitation energy of the first material is 2.38 eV. A lowest spin doublet excitation energy of the second material is 1.75 eV.

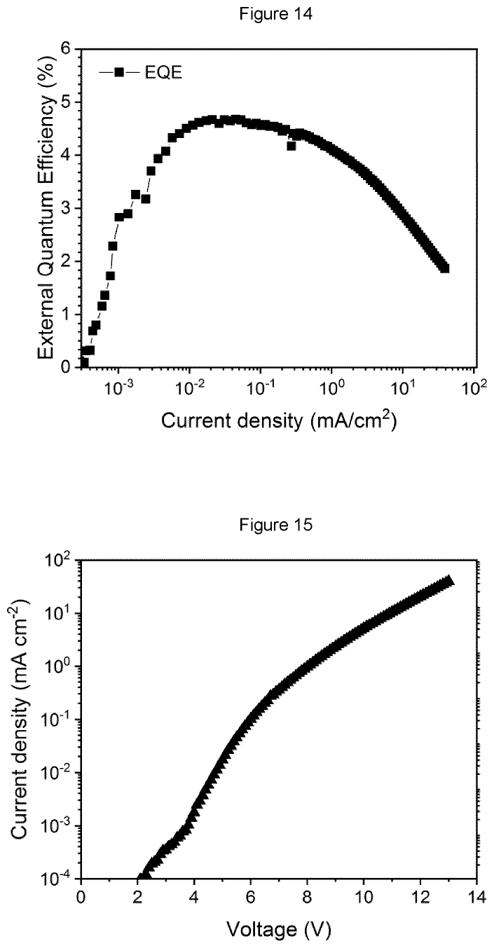

FIG. 14 shows the electroluminescence current density (EQE) device characteristics for the device of Example 4. FIG. 14 shows a plot of the EQE against the current density for the device. A maximum EQE value of 4.5% is obtained for 0.01 mA/cm² to 0.1 mA/cm². An EQE value of 4% is found at 1 mA/cm². The ratio of the EQE value at 1mA/cm² to the maximum EQE value was 0.89. Thus a reasonable electroluminescent efficiency may be achieved, with reduced roll-off at high current densities.

FIG. 15 shows the current density against voltage diode characteristic of the device according to Example 4.

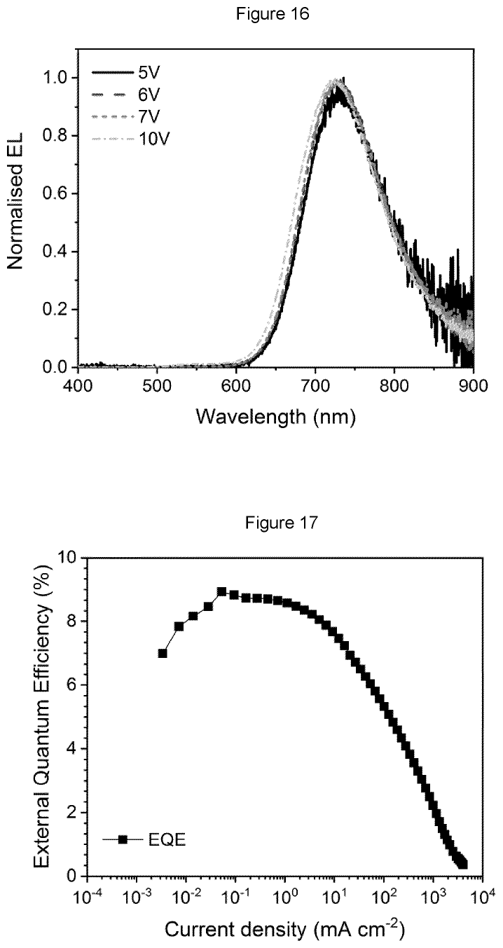

In contrast to FIGS. 7, 10 and 13 for Examples 1, 2 and 3, the electroluminescence profiles show no 4CzIPN contribution (expected ca. 520 nm); all of the electroluminescence contribution is from TTM-3NCz (724 nm, see FIG. 16). This shows that it is possible to remove the emission contribution from the first material. However, a lower efficiency compared to other devices doped with a third material is seen, since the 4CzIPN contribution is removed due to exciton self-quenching effects.

### Example 5

A device according to an embodiment will now be described. A device according to Example 5 was prepared as follows.

The anode comprises ITO. A second layer comprising MoO₃ is formed overlying the anode. The second layer is 6 nm thick. The second layer is a hole injection layer.

An ohmic hole contact third layer of C60 (Buckminsterfullerene, HOMO energy 6.1 eV, LUMO energy 4.5 eV) is formed overlying the second layer, according to the procedure set out in Kotadiya et al. (Nature Photonics, 2019, 13, 765-769, the entire contents of which, including the extended data and supplementary information, are incorporated herein by reference. The ohmic hole contact layer is a 3 nm thick layer.

An emissive layer is formed overlying the ohmic hole contact layer. The emissive layer is 80 nm. The emissive layer comprises a first material, CzDBA, and a second material, TTM-3PCz. The emissive layer comprises 97 wt % CzDBA and 3 wt % TTM-3PCz. A lowest spin singlet excitation energy of the first material is 2.63 eV. A lowest spin triplet excitation energy of the first material is 2.60 eV. A lowest spin doublet excitation energy of the second material is 1.78 eV.

A fifth layer comprising 2,2′,2″-(1,3,5-benzinetriyl)-tris(1-phenyl-1-H-benzimidazole) (TPBi) is formed overlying the light-emitting layer. This layer is the ohmic electron contact. The fifth layer is 4 nm.

The cathode is formed overlying the fifth layer, and comprises Al. The cathode is formed in a 100 nm thick layer.

FIG. 17 shows the electroluminescence current density (EQE) device characteristics for the device of Example 5. FIG. 17 shows a plot of the external quantum efficiency (EQE) against the current density for the device. A maximum EQE value of 9% is obtained for 0.1 to 1 mA/cm². An EQE value of 8% is found at 10 mA/cm². The ratio of the EQE value at 10 mA/cm² to the maximum EQE value was 0.89. Thus a reasonable electroluminescent efficiency may be achieved, with reduced roll-off at high current densities.

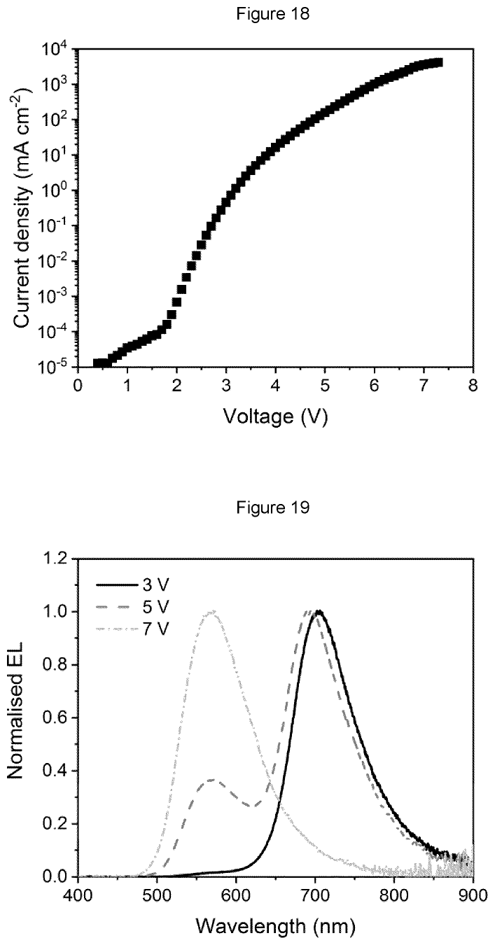

FIG. 18 shows the current density against voltage diode characteristic of the device according to Example 5.

Similar to FIGS. 7, 10 and 13, the electroluminescence profiles show increasing CzDBA contribution at 568 nm and decreasing TTM-3PCz contribution at 704 nm to the total device colour with increasing voltage, as can be seen in FIG. 19.

### Second Embodiment

In a second embodiment, the emissive layer 4 comprises a host comprising a first material, being a first organic semiconductor compound, and a third material, being a third organic semiconductor compound. The emissive layer further comprises a dopant which is a second material, being a second different organic semiconductor compound that has a spin doublet ground state. The host is also referred to as the donor D and the dopant is also referred to as the acceptor A. The first material is a closed shell molecule and has a singlet spin 0 ground state. The spin singlet ground state of the first material is referred to as S₀(1). The dopant is an open shell molecule and has a spin doublet ground state. The spin doublet ground state is referred to as D₀. The dopant comprises a singly occupied molecular orbital (SOMO) in the ground state, giving an overall spin-½ doublet ground state. The third material is a closed shell molecule and has a singlet spin 0 ground state. The spin singlet ground state of the third material is referred to as S₀(3).

During operation, a voltage is applied across the device. Electrons are injected from the cathode and holes are injected from the anode. Charge trapping occurs at the first material and third material. The first material and third material form an exciplex. This is an example of an intermolecular charge transfer system. Holes occupy the highest occupied molecular orbitals (HOMOs) of the first material and electrons occupy the lowest unoccupied molecular orbitals (LUMOs) in the third material. Recombination occurs between the first material and the third material (instead of on the first material or the third material) generating singlet or triplet exciplexes. An electron in the LUMO of the third material and a hole in the HOMO of the first material form an exciplex. Formation of an exciplex between a first material molecule and third material molecule occurs. Electrical excitation leads to the formation of singlet spin 0 exciplex with 25% probability and triplet spin 1 exciplex with 75% probability. The spin singlet exciplex excited state is referred to as S₁ and the spin triplet exciplex excited state is referred to as T₁.

Energy from the exciplex is transferred to the second material (acceptor). The acceptor is transferred from the spin doublet ground state to the spin doublet excited state. The spin doublet excited state is referred to as D₁. The acceptor then emits fluorescent light on returning to the spin doublet ground state. The acceptor is a doublet emitter. Spin-allowed emission, i.e. fluorescence, in the molecules of the acceptor originates from the lowest-lying doublet excited state. The acceptor may be a radical emitter.

During operation, a voltage is applied across the device, forming spin singlet excited exciplex states and spin triplet excited exciplex state in the host, wherein energy is transferred from the spin singlet excited exciplex state and the spin triplet excited exciplex state to create an excited doublet state in the second material (acceptor), wherein the acceptor emits fluorescent light transitioning from a spin doublet excited state to a ground state.

The first material and the third material are selected to set up an intermolecular charge transfer system. The energy of the lowest unoccupied molecular orbital of the first material is higher than the energy of the lowest unoccupied molecular orbital of the third material. The energy of the highest occupied molecular orbital of the first material is higher than the energy of the highest occupied molecular orbital of the third material. Moreover, the energy of the highest occupied molecular orbital of the first material is lower than the energy of the lowest unoccupied molecular orbital of the third material.

Furthermore, the energy difference between the highest occupied molecular orbital of the first material and the lowest unoccupied molecular orbital of the third material is greater than the lowest spin doublet excitation energy of the second material. This allows energy transfer from the exciplex excited state to the dopant.

In the second embodiment, energy is transferred from the exciplex (formed from the first material and third material) to the second material. Intermolecular charge transfer excitons are formed between the first and third materials, and these excitons undergo energy transfer to the second material. In the first embodiment on the other hand, energy is transferred from excited states in the first material to the second material.

As is described above in the first embodiment, the first material may be a TADF material. In the second embodiment, on the other hand the first and third materials may form an exciplex. In the second embodiment the first and third materials may form a thermally-activated delayed fluorescent (TADF) exciplex.

In the first embodiment, the first material may comprise a ‘donor’ moiety and an ‘acceptor’ moiety. This leads to a strong charge-transfer character for the first excited state, with substantial spatial separation and little overlap between the ‘donor’-centred HOMO and the ‘acceptor’-centred LUMO. In the second embodiment, the first material is preferably a hole transport compound and/or the third material is preferably an electron transport material. This leads to intermolecular charge transfer between the first and third materials in the exciplex, with substantial spatial separation and little overlap between the HOMO, which is centred on the first material, and the LUMO, which is centred on the third material.

In the first embodiment, the first material may comprise an electron rich component and an electron deficient component. In the second embodiment, on the other hand, the first material may be an electron rich material and the third material may be an electron deficient material.

The LUMO energy level of the third material is higher than the SOMO energy level of the second material for reduction. This reduces charge transfer, specifically electron transfer, from the second material to the third material following excitation. The HOMO energy level of the first material is lower than the HOMO energy level of the second material. This reduces charge transfer, specifically hole transfer, from the second material to the first material following excitation.

Increasing the % wt of the host in the emissive layer relative to the % wt of the second material (dopant) in the emissive layer acts to increase the probability of charge trapping occurring on the host. An amount of the host in the emissive layer is greater than an amount of the second material in the emissive layer. When the donor is in excess versus the acceptor material, the charge trapping is more likely at the donor sites. This is a kinetic effect, resulting in electron-hole recombination preferentially occurring at the donor sites.

It is considered that Dexter-type energy transfer occurs from the spin triplet exciplexes to the spin doublet ground state as described above for the first embodiment. An excited electron is transferred from the exciplex, and in particular from a third material, to an acceptor molecule, in exchange for a ground-state electron being transferred from the acceptor molecule to the exciplex, in particular to the first material. An excited electron is transferred from the third material in the triplet exciplex to the acceptor molecule in the spin doublet ground state, forming a spin doublet excited state, and a ground state electron is transferred from the acceptor molecule in the spin doublet ground state to the first material in the triplet exciplex, forming a spin singlet ground state in the first material and the third material. The doublet spin property allows Dexter-type energy transfer from the triplet exciplex.

The lowest spin triplet excitation energy of exciplex is greater than the lowest spin doublet excitation energy of the second material. This permits Dexter energy transfer to occur from the spin triplet exciplexes to the spin doublet ground state. Thermodynamically, the lowest energy excited state is the spin doublet excited state, so energy transfer occurs from the exciplex to the second material.

The amount of the host and the second material in the emissive layer 4 may be selected in order to increase the efficiency of Dexter transfer between the spin triplet excited state in the exciplex and the spin doublet ground state in the second material. In particular, an amount of the host, comprising the first material and the third material in the emissive layer is greater than an amount of the second material in the emissive layer.

It is considered that Förster-type energy transfer occurs from the spin singlet exciplexes to the spin doublet ground state as described above for the first embodiment.

A lowest spin singlet excitation energy of the exciplex is greater than a lowest spin doublet excitation energy of the second material. This permits Förster transfer to occur from the exciplex to the second material. Thermodynamically, the lowest energy excited state is the spin doublet excited state, so energy transfer occurs from the exciplex to the second material. As has been described above for the first embodiment, the efficiency of the singlet-doublet energy transfer is increased with higher absorption extinction coefficient ε of the second material. Furthermore, the efficiency of the Förster transfer is increased with increased overlap of the exciplex emission spectrum with the acceptor absorption spectrum. Increased spectral overlap between the exciplex S₁ fluorescence with the doublet absorption provides increased efficiency of the singlet-doublet energy transfer.

To promote energy transfer from the exciplex to the second material, at least one of the following expressions is satisfied:

E_{S1}(1), E_{T1}(1)>E_{S1}, E_{T1}>E_{D1}(A) (iv)

E_{S1}>E_{T1}(1)>E_{D1}(A) (v)

E_{S1}(3), E_{T1}(3)>E_{S1}, E_{T1}>E_{D1}(A) (vi)

E_{S1}, E_{T1}>E_{T1}(3)>(A) (vii)

In these expressions E_{S1} and E_{T1} represent the lowest spin singlet and triplet excitation energy levels of the exciplex, E_{S1}(1) and E_{T1}(1) represent the lowest spin singlet and triplet excitation energy levels of the first material, E_{S1}(3) and E_{T1}(3) represent the lowest spin singlet and triplet excitation energy levels of the third material, and E_{D1}(A) represents the lowest spin doublet excitation energy of the second material. The lowest spin triplet energy of the first and third material is higher than the spin doublet of second material in order to provide increased light emission from the radical.

When a voltage is applied, charge trapping occurs at the host, which is a combination of closed-shell compounds, to form singlet S₁ and triplet T₁ exciplex states. Due to the doublet-spin nature of the second material, which is an open-shell compound A, the energy from both singlet and triplet exciplex states can be transferred to A directly, during device operation. The doublet emitters A receive energy to form doublet-spin excitons D₁ for light emission. The mode of operation comprises: charge trapping at the first and third materials, closed-shell molecule sites form singlet and triplet exciplexes which can undergo direct energy transfer to the doublet emitter A to generate luminescent doublet excitons. Emission occurs from a spin doublet excited state. Since energy is harvested from both the triplet and singlet excited states, this mode of operation is believed to have possible electroluminescence efficiency of up to 100%.

In the device described in relation to the second embodiment, the charge trapping process is also moved away from the doublet emitters, and therefore good charge balance may be obtained resulting in operational stability. Charge trapping occurs at the host which comprises a combination of closed-shell compounds (first and third materials), energy from both singlet and triplet exciplexes are transferred to a second material which is an open shell compound A, and doublet emitters form doublet-spin excitons D₁ for light emission. Good operational stability may thus be achieved.

In an embodiment, a luminescence lifetime of less than 1 microsecond may be obtained, measured using a pulsed-laser excitation source at 400 nm and an intensified-CCD (ICCD) camera for time-resolved photoluminescence detection of the excited film. In an embodiment, a luminescence lifetime of less than 100 nanoseconds may be obtained. In an embodiment, a luminescence lifetime of 10 to 100 nanoseconds may be obtained.

In the device described in relation to the second embodiment, charge trapping occurs at the first material and the third material, and energy from both singlet and triplet exciplexes is transferred to the second material. The second material then emits fluorescent light on returning to the spin doublet ground state. Doublet spin ½ emitter molecules can therefore be used to harvest energy during organic electroluminescent device operation. This may result in increased efficiency and improved roll-off characteristics. Using doublet emitters to harvest energy from both singlet and triplet exciplex states directly in an electroluminescent device may reduce device instability and charge balance issues associated with direct charge trapping on the doublet emitters.

As described above in expressions (iv) to (vii), the lowest spin singlet excitation energy level of the exciplex E_{S1} is greater than the lowest spin doublet excitation energy of the second material E_{D1}(A). When the lowest spin singlet excitation energy level of the exciplex is closer to the lowest spin doublet excitation energy of the second material, efficiency of the device may be increased. This allows lower driving voltages in OLED operation. In an embodiment, the difference between the lowest spin singlet excitation energy level of the exciplex and the lowest spin doublet excitation energy of the second material is less than 1.5 eV. In a further embodiment, a difference between the lowest spin singlet excitation energy level of the exciplex and the lowest spin doublet excitation energy of the second material is less than 1.2 eV. In a yet further embodiment, a difference between the lowest spin singlet excitation energy level of the exciplex and the lowest spin doublet excitation energy of the second material is less than 1 eV. In a yet further embodiment, a difference between the lowest spin singlet excitation energy level of the exciplex and the lowest spin doublet excitation energy of the second material is less than 0.7 eV.

As has been described above, in the device of FIG. 1, the emissive layer comprises the host and the second material. In an embodiment, an amount of the host in the emissive layer is greater than an amount of the second material in the emissive layer. This reduces the probability of charge trapping occurring on the second material molecule, thereby increasing the probability of charge trapping occurring on the host.

The organic light emitting device of the second embodiment may comprise one or more additional layers in addition to the emissive layer. For example, the organic light emitting device of the invention may comprise a hole injection layer, a hole transport layer, an electron transport layer and/or an electron injection layer. The device according to an embodiment shown in FIG. 1 comprises a hole injection layer 2 provided overlying the anode 1 and a hole transport layer 3 provided overlying the hole injection layer 2. The emissive layer 4 is provided overlying the hole transport layer 3. An electron transport layer 5 is provided overlying the emissive layer 4, an electron injection layer 6 is provided overlying the electron transport layer 5, and the cathode 7 is provided overlying the electron injection layer 6. Various other layers that are commonly used in OLED devices may optionally be included. The device is designed so that charge trapping occurs in the host, between the first material and the third material, to give the exciplex.

### Host

A device according to the second embodiment includes an emissive layer comprising a host. The host comprises host materials in the form of the first material and the third material.

The host is an exciplex host, in other words a combination of a first material and a third material which form an exciplex. The host may be a thermally-activated delayed fluorescent (TADF) host.

In an embodiment, the exciplex has a relatively low exchange energy. In an embodiment, the difference between the lowest singlet excitation energy level of the exciplex and the lowest triplet excitation energy level of the exciplex is less than 0.2 eV, in other words the following expression is satisfied:

|E_{S1}−E_{T1}|<0.2 eV (viii)

A lower exchange energy may reduce energy losses during operation and improve the overall power conversion efficiencies. The low singlet-triplet energy difference is achieved by an intermolecular charge transfer, as opposed to the intramolecular charge transfer discussed for the first embodiment.

In an embodiment, the ratio of the first material to the third material in the emissive layer is in the range of from about 5:1 to about 1:5, from about 4:1 to about 1:4, from about 3:1 to about 1:3, from about 2:1 to about 1:2, from about 1.5:1 to about 1:1.5, from about 1.25:1 to about 1:1.25, from about 1.1:1 to about 1:1.1, or from about 1.05:1 to about 1:1.05. In an embodiment, the ratio of the first material to the third material in the emissive layer is about 5:1, about 4:1, about 3:1, about 2:1, about 1.5:1, about 1.1:1, about 1.05:1, about 1:1, about 1:1.05, about 1:1.1, about 1:1.5, about 1:2, about 1:3, about 1:4, or about 1:5 by weight. In a preferred embodiment, the ratio of the first material to the third material in the emissive layer is about 1:1 by weight.

In an embodiment, the emissive layer comprises the host (first material and the third material) in a combined amount of from about 70% to about 99% by weight, from about 75% to about 98.5% by weight, from about 80% to about 98% by weight, from about 85% to about 97.5% by weight, from about 90% to about 97% by weight, or from about 95% to about 96.5% by weight based on the total weight of the emissive layer. In an embodiment, the emissive layer comprises the host (first material and the third material) in a combined amount of about 60%, about 65%, about 70%, about 75%, about 80%, about 85%, about 90%, about 95%, about 95.5%, about 96%, about 96.5%, about 97%, about 97.5%, about 98%, about 98.5%, or about 99% by weight based on the total weight of the emissive layer. In an embodiment, the emissive layer comprises the host in a combined amount of about 97% by weight based on the total weight of the emissive layer.

The first material is an material in the form of a closed-shell component. The first material has a spin singlet ground state.

In an embodiment, the first material is a hole transport compound. The first material is an electron acceptor. The first material may be, for example, a carbazole derivative or an aromatic amine compound. Various materials are known for use as hole transport compounds in an organic light emitting device. Examples of the first material may include tris(4-carbazoyl-9-ylphenyl)amine (TCTA), 9,9′-Diphenyl-9H,9′H-3,3′-bicarbazole (BCzPh), 1,1-Bis[(di-4-tolylamino)phenyl]cyclohexane (TAPC), 9-Phenyl-3,6-bis(9-phenyl-9Hcarbazol-3-yl)-9H-carbazole (Tris-PCz), 1,3-bis(9-carbazolyl)benzene (mCP), 4,4′-bis(N-carbazolyl)-1,1′-biphenyl (CBP), 3,3-bis(carbazol-9-yl)biphenyl (mCBP), N,N′-di(1-naphthyl)-N,N′-diphenyl-(1,1′-biphenyl)-4,4′-diamine (NPB), 4,4′,4″-tris[phenyl(m-tolyl)amino]triphenylamine (m-MTDATA), and N,N′-bis(3-methylphenyl)-N,N′-diphenylbenzidine (TPD). In preferred embodiments, the first material is CBP, TCTA, BCzPh, TAPC, Tris-PCz, mCP, mCBP, NPB, m-MTDATA, or TPD.

In an embodiment, the third material is an electron transport compound. The third material is an electron donor. Various materials are known for use as electron transport compounds in an organic light emitting device. For example, the third material may be a π-electron deficient heteroaryl compound, a phosphine oxide group-containing compound, a sulfur oxide group-containing compound, or a triazine derivative. Examples of the third material may include bis-4,6-(3,5-di-2-pyridylphenyl)-2-methylpyrimi-dine (B2PYMPM), bis-4,6-(3,5-di-3-pyridylphenyl)-2-methylpyrimi-dine (B3PYMPM), bis-4,6-(3,5-di-4-pyridylphenyl)-2-methylpyrimi-dine (B4PYMPM), bis-4,6-(3,5-di(pyridin-4-yl)phenyl)-2-phenylpyrimidine (B4PYPPM), 3-(4,6-Diphenyl-1,3,5-triazin-2-yl)-9-phenyl-9H-carbazole (DPTPCz), 2,4,6-tris(biphenyl-3-yl)-1,3,5-triazine (T2T), 2,2′,2″-(1,3,5-benzenetriyl)tris-[1-phenyl-1H-benzimidazole] (TPBi), tris(2,4,6-trimethyl-3-(pyridin-3-yl)phenyl)borane (3TPYMB), 1,3-bis[3,5-di(pyridin-3-yl) phenyl]benzene (BmPyPB), 1,3-bis[3,5-di(pyridin-3-yl)phenyl]benzene (BmPyPhB), 3,3′,5,5′-tetra[(M-pyridyl)-phen-3-yl]biphenyl (BP4mPy), 3,3′[5′[3-(3-pyridinyl)phenyl][1,1′:3′,1″-terphenyl]-3,3′-diyl]bispyridine (TmPyPB), bis-9,9′-spirobi[fluoren-2-yl]-methanone (BSFM), (1,3,5-Triazine-2,4,6-triyl)tris(benzene-3,1-diyl)tris(diphenylphosphine oxide) (PO-T2T), and dibenzo[b,d]thiophene-2,8-diylbis(diphenylphosphine oxide) (PO15). In preferred embodiments, the third material is B4PYMPM, B4PYPPM, 3TPYMB, BmPyPB, BSFM, B3PYMPM or TPBi.

The first and third materials are organic semiconductors with conjugated pi-systems. These materials include electron transport, hole transport and host materials which can be used in optoelectronic devices such as light-emitting diodes and photovoltaics.

Examples of the combination of first material and third material which form an exciplex may include TCTA:B4PYMPM, TCTA:B3PYMPM, TCTA:DPTPCz, TCTA:T2T, TCTA:TPBi, TCTA:3TPYMB, TCTA:BmPyPB, TCTA:BSFM, TAPC:B4PYMPM, TAPC:B3PYMPM, TAPC:TPBi, TAPC:3TPYMB, TAPC:DPTPCz, TAPC:BmPyPB, TAPC:BSFM, CBP:B3PYMPM, mCP:B3PYMPM, NPB: B3PYMPM, NPB:T2T or NPB:BSFM.

The first material and the third material interact to form an exciplex when voltage is applied across the emissive layer or device. The energy of the LUMO of the first material is higher than the energy of the LUMO of the third material. The energy of the HOMO of the first material is higher than the energy of the HOMO of the third material. The energy difference between the energy of the HOMO of the first material and the LUMO of the third material is greater than the energy of the first doublet excited state of the second material. The host is an exciplex host in which the first material and the third different material combine together to form an exciplex.

### Second Material

Various examples and description of the second material are provided in the first embodiment. As described in the first embodiment, given a second material, the host materials may be selected to satisfy at least one of expressions (iv) to (vii) above. Given a specific second material, a suitable host may be selected to satisfy energy transfer to the radical.

The energy of the first doublet excited state of the second material is smaller than the energy difference between the energy of the HOMO of the first material and the LUMO of the third material.

In an embodiment, the emissive layer comprises the second material in an amount of from about 1% to about 30% by weight, from about 1.5% to about 25% by weight, from about 2% to about 20% by weight, from about 2.5% to about 15% by weight, from about 3% to about 10% by weight, or from about 4.5% to about 5% by weight based on the total weight of the emissive layer. In an embodiment, the emissive layer comprises the second material in an amount of about 1%, about 1.5%, about 2%, about 2.5%, about 3%, about 3.5%, about 4%, about 4.5%, about 5%, about 10%, about 15%, about 20%, about 25%, about 30%, about 35%, or about 40% by weight based on the total weight of the emissive layer. In a preferred embodiment, the emissive layer comprises the second material in an amount of about 3% by weight based on the total weight of the emissive layer.

### Anode, Cathode, Hole Injection Layer, Electron Injection Layer, Hole Transport Layer and Electron Transport Layer

Various examples and description of the anode, cathode, hole injection layer, electron injection layer, hole transport layer and electron transport layer are provided in the first embodiment.

### Emissive layer

Various specific examples of the combination of materials included in the emissive layer of the second embodiment will now be described.

| First | Second | Third | Singlet excitation |
|---|---|---|---|
| material | material | material | energy exciplex (eV) |
| CBP | TTM-3PCz | B3PYMPM | 2.5 |
| TCTA | TTM-3PCz | B3PYMPM | 2.3 |
| CBP | TTM-TPA | B3PYMPM | 2.5 |
| TCTA | TTM-TPA | B3PYMPM | 2.3 |
| TAPC | TTM-TPA | B3PYMPM | 2.0 |
| TCTA | TTM-3PCz | TPBi | 3.1 |
| mCP | TTM-3PCz | B3PYMPM | 2.4 |
| NPB | TTM-3PCz | B3PYMPM | 2.0 |
| TCTA | TTM-3PCz | B4PYMPM | 2.2 |
| TCTA | TTM-3PCz | 3TPYMB | 2.5 |
| TCTA | TTM-3PCz | BmPyPB | 3.2 |

For B3PYMPM: HOMO energy is 7.0 eV, LUMO energy is 3.4 eV, lowest spin singlet excitation energy is 2.97 eV and a lowest spin triplet excitation energy is 2.68 eV.

For TCTA: HOMO energy is 5.83 eV LUMO energy is 2.43 eV, lowest spin singlet excitation energy is 3.2 eV and a lowest spin triplet excitation energy is 2.8 eV.

For CBP: HOMO energy is 6 eV, LUMO energy is 2.9 eV, lowest spin singlet excitation energy is 3.32 eV and a lowest spin triplet excitation energy is 2.49 eV.

For TPBi: HOMO energy is 6.2-6.7 eV, LUMO energy is 2.8 eV, lowest spin singlet excitation energy is 3.4 eV and a lowest spin triplet excitation energy is 2.7 eV. Various specific examples of the composition of the emissive layer will now be described:

| Example | First material | Second material | Third material |
|---|---|---|---|
| 6 | 48.5% CBP | 3% TTM-3PCz | 48.5% B3PYMPM |
| 7 | 48.5% TCTA | 3% TTM-3PCz | 48.5% B3PYMPM |
| 8 | 48.5% TCTA | 3% TTM-3PCz | 48.5% TPBi |

Various examples of specific devices of the second embodiment will now be described in the following section. In these examples, device stability is improved and roll-off (the drop in electroluminescent efficiency with increasing current density) is reduced. A low turn on voltage is also seen.

### Example 6

A device according to an embodiment will now be described. A device according to Example 6 was prepared as follows.

The anode comprises ITO. A second layer comprising MoO₃ is formed overlying the anode. The second layer is 3 nm thick. The second layer is a hole injection layer. A third layer comprising TAPC is formed overlying the second layer. The third layer is 30 nm thick. The third layer is a hole transport layer. A fourth layer is formed overlying the third layer. The fourth layer comprises TCTA. The fourth layer is 10 nm thick. The fourth layer is a hole transport layer

An emissive layer is formed overlying the hole injection layer. The emissive layer is 30 nm thick. The emissive layer comprises a first material, CBP, a second material, TTM-3PCz, and a third material, B3MYMPM. The emissive layer comprises 48.5% CBP, 3% TTM-3PCz and 48.5% B3MYMPM.

A sixth layer comprising B3PYMPM is formed overlaying the emissive layer. The sixth layer is 10 nm thick. The sixth layer is an electron-transport layer. A seventh layer comprising TPBi is formed overlaying the sixth layer. The seventh layer is 60 nm thick. The seventh layer is an electron-transport layer. The seventh layer is included because having staggered transport layers with small energy steps can help to reduce turn on voltage in a device. An eighth layer comprising LiF is formed overlying the electron transport layer. The eighth layer is the electron injection layer. The eighth layer is 0.8 nm. The cathode is formed overlying the eighth layer, and comprises Al. The cathode is formed in a 100 nm thick layer.

Two hole transport layers (the third layer and the fourth layer) and two electron transport layers (the sixth layer and the seventh layer) are included in the device. Including the staggered transport layers with small energy steps can help to reduce turn on voltage in a device.

FIG. 21 shows the electroluminescence current density (EQE) device characteristics for the device of Example 6. FIG. 21 shows a plot of the EQE against the current density for the device. A maximum EQE of 6.9% is found at 0.1 mA/cm², and an EQE of 6.6% is found at 1 mA/cm². The ratio of the EQE value at 1 mA/cm² to the maximum EQE value was 0.96. Thus a high electroluminescent efficiency may be achieved, with reduced roll-off at high current densities. The EQE at 1 mA/cm² is greater than 0.95 of the maximum EQE. An EQE of 5.8% is found at 10 mA/cm².

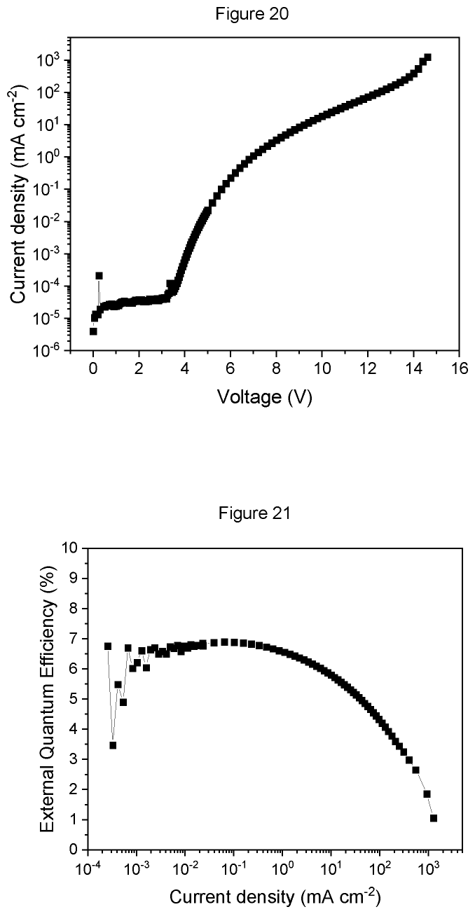

FIG. 20 shows the current density against the voltage. FIG. 20 plots the diode characteristic of the current density against voltage. The device of Example 6 has a turn-on voltage of 3.2 V.

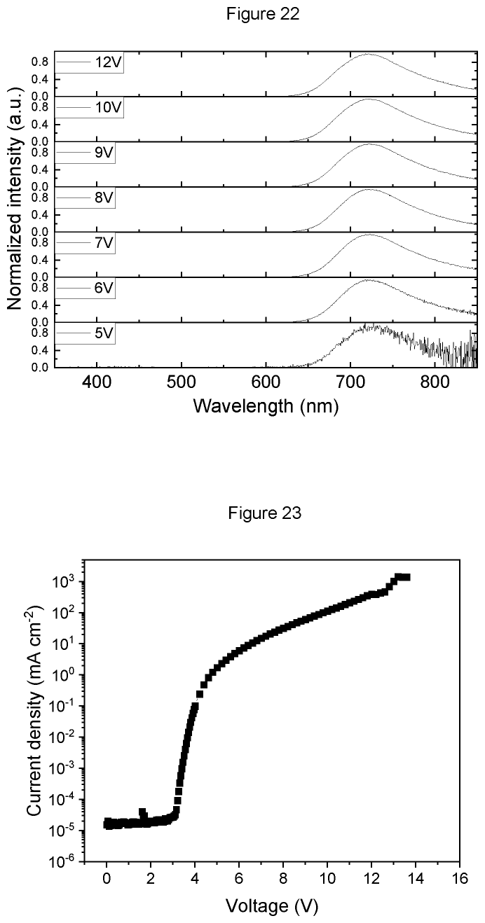

FIG. 22 shows normalised electroluminescence (EL) profiles for the same device. The electroluminescence peak from the TTM-3PCz appears at 714 nm.

### Example 7

A device according to an embodiment will now be described. A device according to Example 7 was prepared as follows.

The anode comprises ITO. A second layer comprising MoO₃ is formed overlying the anode. The second layer is 3 nm thick. The second layer is a hole injection layer. A third layer comprising TAPC is formed overlying the second layer. The third layer is 30 nm thick. The third layer is a hole transport layer. A fourth layer if formed overlying the third layer. The fourth layer comprises TCTA. The fourth layer is 10 nm thick. The fourth layer is a hole transport layer.

An emissive layer is formed overlying the hole injection layer. The emissive layer is 30 nm thick. The emissive layer comprises a first material, B3PYMPM, a second material, TTM-3PCz, and a third material, TCTA. The emissive layer comprises 48.5% TCTA, 3% TTM-3PCz and 48.5% B3MYMPM.

A sixth layer comprising B3PYMPM is formed overlaying the emissive layer. The sixth layer is 10 nm thick. The sixth layer is an electron-transport layer. A seventh layer comprising TPBi is formed overlaying the sixth layer. The seventh layer is 60 nm thick. The seventh layer is an electron-transport layer. An eighth layer comprising LiF is formed overlying the electron transport layer. The eighth layer is the electron injection layer. The eighth layer is 0.8 nm. The cathode is formed overlying the eighth layer, and comprises Al. The cathode is formed in a 100 nm thick layer.

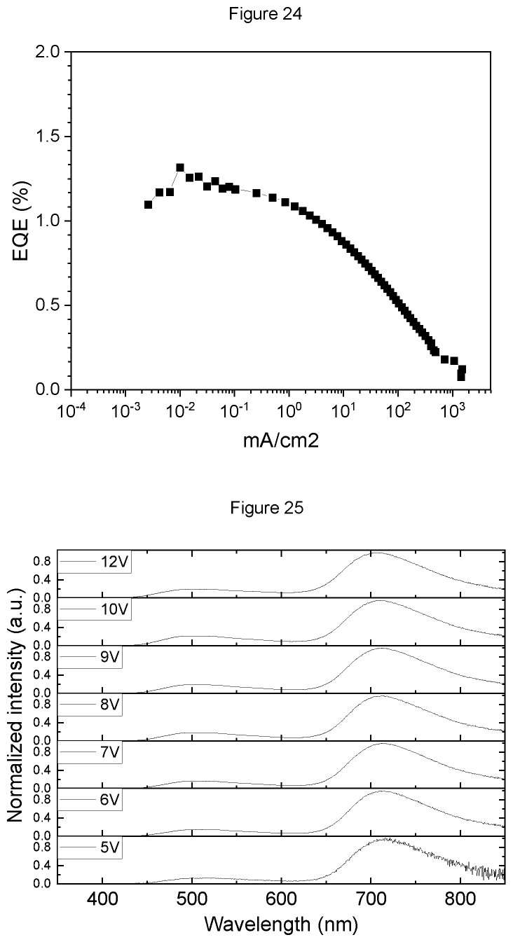

FIG. 24 shows the electroluminescence current density (EQE) device characteristics for the device of Example 7. FIG. 24 shows a plot of the EQE against the current density for the device. A maximum EQE of 1.2% is found at 0.1 mA/cm², and an EQE of 1.1% is found at 1 mA/cm². The ratio of the EQE value at 1 mA/cm² to the maximum EQE value was 0.96. Thus a high electroluminescent efficiency may be achieved, with reduced roll-off at high current densities. The EQE at 1 mA/cm² is greater than 0.95 of the maximum EQE. An EQE of 0.9% is found at 10 mA/cm².

FIG. 23 shows the current density against the voltage. FIG. 23 plots the diode characteristic of the current density against voltage. The device of Example 7 has a turn-on voltage of 3.1 V.

FIG. 25 shows normalised electroluminescence (EL) profiles for the same device. The electroluminescence peak from the TTM-3PCz appears at 714 nm. An increasing contribution from the exciplex appears at 500 nm with increasing voltage.

### Example 8

A device according to an embodiment will now be described. A device according to Example 8 was prepared as follows.

The anode comprises ITO. A second layer comprising MoO₃ is formed overlying the anode. The second layer is 3 nm thick. The second layer is a hole injection layer. A third layer comprising TAPC is formed overlying the second layer. The third layer is 30 nm thick. The third layer is a hole transport layer. A fourth layer if formed overlying the third layer. The fourth layer comprises TCTA. The fourth layer is 10 nm thick. The fourth layer is a hole transport layer.

An emissive layer is formed overlying the hole injection layer. The emissive layer is 30 nm thick. The emissive layer comprises a first material, TCTA, a second material, TTM-3PCz, and a third material, TPBi. The emissive layer comprises 48.5% TCTA, 3% TTM-3PCz and 48.5% TPBi.

A sixth layer comprising TPBi is formed overlaying the emissive layer. The sixth layer is 60 nm thick. The sixth layer is an electron-transport layer. A seventh layer comprising LiF is formed overlying the electron transport layer. The seventh layer is the electron injection layer. The seventh layer is 0.8 nm. The cathode is formed overlying the seventh layer, and comprises Al. The cathode is formed in a 100 nm thick layer.

FIG. 27 shows the electroluminescence current density (EQE) device characteristics for the device of Example 8. FIG. 27 shows a plot of the EQE against the current density for the device. A maximum EQE of 1.6% is found at 0.1 mA/cm², and an EQE of 1.6% is found at 1 mA/cm². The ratio of the EQE value at 1 mA/cm² to the maximum EQE value was 1.00. Thus a high electroluminescent efficiency may be achieved, with reduced roll-off at high current densities. The EQE at 1 mA/cm² is about 1.0 of the maximum EQE. An EQE of 1.2% is found at 10 mA/cm².

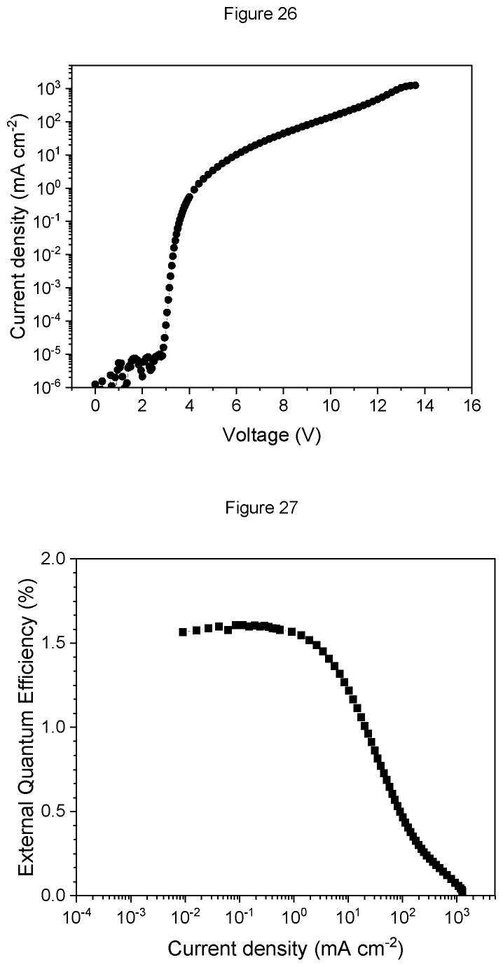

FIG. 26 shows the current density against the voltage. FIG. 26 plots the diode characteristic of the current density against voltage. The device of Example 7 has a turn-on voltage of 3.0 V.

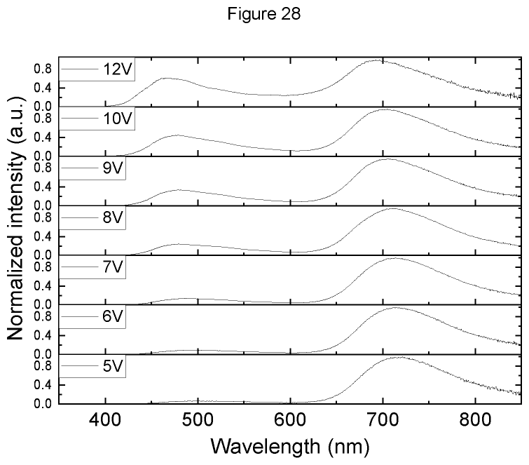

FIG. 28 shows normalised electroluminescence (EL) profiles for the same device. The electroluminescence peak from the TTM-3PCz appears at 714 nm. An increasing contribution from the exciplex appears at 475 nm with increasing voltage.

### Method of Fabricating Devices

An example procedure for fabricating an organic light emitting device in accordance with an embodiment will now be described. The procedure may be used the fabricate the devices of Examples 1 to 5 described above for example. The procedure may also be used the fabricate the devices of Examples 6 to 8 described above for example

First, a general procedure for synthesis of R-substituted TTM radicals will be described.

### Synthetic Example 1

### Preparation of tris(2,4,6-trichlorophenyl)methane (HTTM)

TTM was prepared as reported in Coulson, C. A.; Rushbrooke, G. S. Note on the method of molecular orbitals. Math. Proc. Cambridge 36, 193-200 (1940) (Scheme 1).

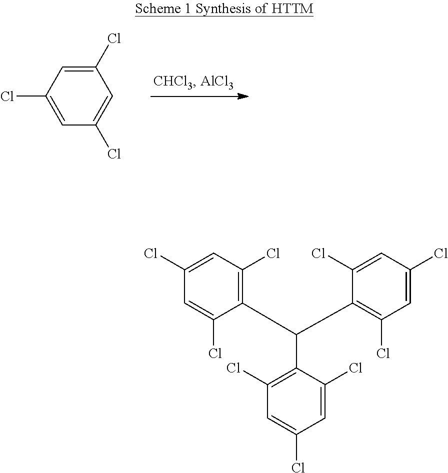 [SMILES: Clc1cc(Cl)cc(Cl)c1 ; Clc1cc(Cl)c(C(c2c(Cl)cc(Cl)cc2Cl)c2c(Cl)cc(Cl)cc2Cl)c(Cl)c1]

### Preparation of R-Substituted HTTM Derivatives

A general synthetic method for preparing substituted HTTM derivatives from HTTM is outlined in Scheme 2.

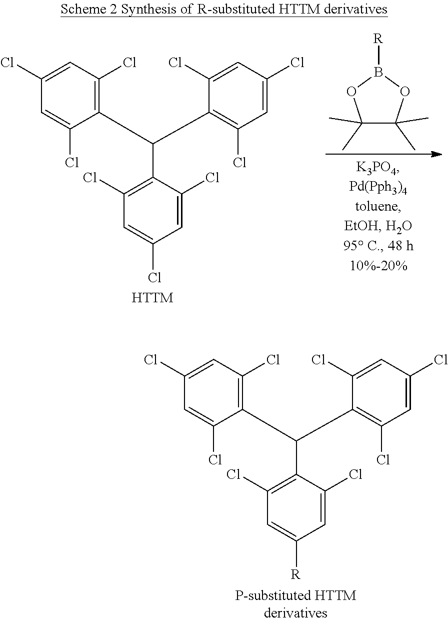

HTTM (1.24 mmol) and the appropriate R-substituted pinacolborane (1.36 mmol) were dissolved in a mixed solvent of toluene (12 mL), K₃PO₄ aqueous solution (8 mL, 2 M) and ethanol (4 mL), and catalyst Pd(PPh3)4 (0.07 mmol) was added under argon atmosphere. The mixture was stirred at 95° C. for 48 h under argon atmosphere and in the dark. Following this, the reaction mixture was allowed to rest and cool to room temperature. 5% hydrochloric acid was then introduced until no bubbles were generated upon addition. After extraction with dichloromethane, the organic layer was collected and dried. The solvent was removed under vacuum and the crude product was purified by silica gel column chromatography (using petroleum ether: dichloromethane=10:1, v/v). Desired R-substituted HTTM derivatives compounds were obtained as white solids

### Preparation of R-Substituted TTM Radical Derivatives

The general synthetic method for preparing substituted TTM radicals from substituted HTTM derivatives is outlined in Scheme 2.

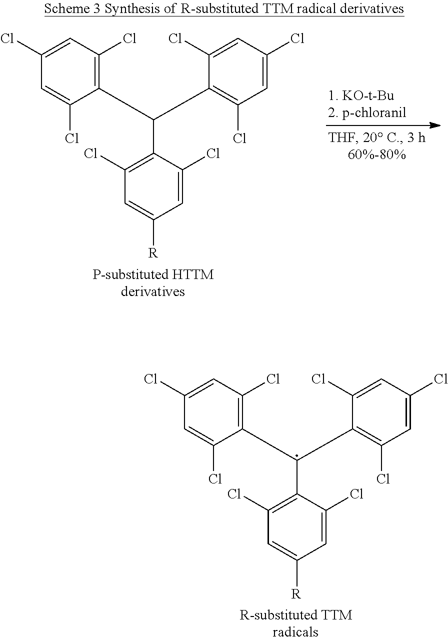

Under argon atmosphere and in the dark, the H compound (1.0 eq.) was dissolved in dry THF. Next, the KOtBu (2.0 eq.) was added, and the solution acquired a claret colour. The solution was stirred for 1.5 h in the dark at room temperature, and then p-chloranil (2.7 eq.) was added. Following this, the solution was stirred for further 1.5 h. After the reaction finished, the solvent was removed under vacuum and the crude product was purified by silica gel column chromatography (using petroleum ether: dichloromethane=10:1, v/v).

The above outlines the general synthetic procedures for preparing substituted TTM radicals by Route 1 and Route 2. At least TTM-3NCz and TTM-3PCz radical derivatives are prepared in this way, wherein for 3NCz, R is 3-substituted-9-(naphthalen-2-yl)-9H-carbazole, and for 3PCz, R is 3-substituted-9-phenyl-9H-carbazole.

### Synthetic Example 2

### Preparation of TTM-Radical Derivatives

In another embodiment, TTM-radical derivatives can be prepared according to the following procedure.

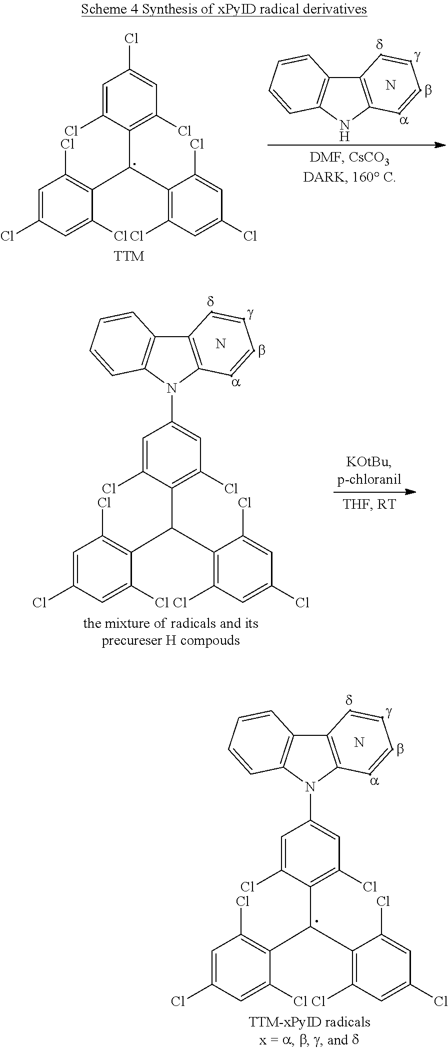

A mixture of TTM (1.32 g, 2.38 mmol), carboline (α-, β-, γ- or δ-carboline) (0.2 g, 1.19 mmol), anhydrous Cs₂CO₃ (0.88 g, 2.62 mmol) and DMF (20 ml) in a 100 ml round-bottom flask was stirred at 160° C. for 12 h under argon atmosphere and in the dark. After the reaction mixture cooled to room temperature, it was poured into (0.2 M) hydrochloric acid solution, and the precipitate was filtered and washed with water three times. The crude product was dissolved in dichloromethane and further extracted with water and dichloromethane. The organic layer was dried over MgSO4, and evaporated under vacuum. The crude product was purified by silica gel column chromatography using the mixture of petroleum ether and ethyl acetate as the eluent, and the desired products H Compounds (mixtures of H compound and radical) were obtained.

### Synthetic Example 3

### Preparation of Devices

The electroluminescent devices are then fabricated by vacuum vapour deposition. The devices were fabricated using a high vacuum deposition method whereby all layers were deposited at a rate<2 Å/s. The chamber base pressure was 10-7 Torr. The anode material is formed into a thin film by vapour deposition onto an ITO substrate. The inorganic layers (e.g. MoO₃ hole injection layer and LiF electron injection layer) were deposited at rates of 0.1-0.2 Å/s using resistive boats. The organic layers (e.g. TAPC hole transport layer, B3PYMPM electron transport layer, 4CzIPN first material, TTM-3PCz second material, CBP third material) were deposited at rates of 0.05-2 Å/s using effusion sources with alumina crucibles. The source temperature for organic deposition is 100° C.-500° C. Layers containing mixture of species (e.g. first, second and third materials) are achieved by simultaneous co-deposition with control over the relative deposition rates. Resistive sources were used for the metal cathode deposition at a rate of 1-3 Å/s. An electrode mask may be used for the metal cathode layer to define the pixel area. To avoid decomposition of the second material, the temperature for deposition of the second material should be lower than the temperature corresponding to 5% decomposition of the second material as measured by thermogravimetric analysis.

The above describes an example method of fabricating an organic light emitting device, comprising: forming an emissive layer between an anode and a cathode, wherein the emissive layer comprises a first material which is an organic semiconductor compound and a second material which is a different organic semiconductor compound that has a spin doublet ground state; and wherein a lowest spin singlet excitation energy of the first material and a lowest spin triplet excitation energy of the first material are greater than a lowest spin doublet excitation energy of the second material.

### Measurements

Details of example procedures for measurement of various properties that have been described in the above will now be provided.

The lowest spin triplet excitation energy of the first material can be determined from phosphorescence spectra. The measurement is performed at low temperature (about 77 K with N₂ cryostat, or lower temperature) so that the slow phosphorescence component to be measured is faster than non-radiative transitions such as T₁ to S₀ or thermally activated delayed fluorescence emission following reverse intersystem crossing (T₁ to S₁ to S₀+hv).

An example procedure for measuring the lowest spin triplet excitation energy of the first material will now be described. A sample of the material is measured in an N₂ cryostat. The sample is prepared as a film as it would be for the emissive layer for the device, i.e. including the second material and the host material where relevant. The sample is photo-excited with a pulsed laser of higher energy than the absorption onset. The energy of absorption onset may be determined from a UV-Vis absorption spectrum. The resultant light emission is then recorded by a time-resolved spectrometer, for example an intensified charge-coupled device camera. Light emission for 1 μs after the laser pulse onwards is assigned to the spin triplet T₁ phosphorescence, whereby the triplet states are populated following intersystem crossing from the singlet S₁ state, which happens in competition with S₁ fluorescence. A phosphorescence spectrum is produced from the measurement, having wavelength on the x-axis, with emission on the y-axis. From the triplet phosphorescence profile, the 0-0 vibronic peak is identified as the highest energy peak. The 0-0 vibronic peak should then be related to T₁.

An example procedure for measuring the lowest spin singlet excitation energy will now be described. The samples are photoexcited with a pulsed laser of higher energy than the absorption onset. The resultant light emission is then recorded by a time-resolved spectrometer, for example an intensified charge-coupled device camera. Light emission for 1 ns-10 ns after the laser pulse can be attributed to the singlet S₁ fluorescence spectrum. Prior to 1 ns, there may contribution of ‘hot’ singlet fluorescence prior to vibrational relaxation. A fluorescence spectrum is produced from the measurement, having wavelength on the x-axis, with emission on the y-axis. From the singlet fluorescence profile, the 0-0 vibronic peak should then be related to S₁.

The lowest spin triplet excitation energy and lowest spin singlet excitation energy of an exciplex can be measured in the same way using films of blended first and third materials as used in the emissive layer for the device.

The lowest spin doublet excitation energy of the second material can be determined from luminescence spectra in a similar manner to the lowest spin singlet excitation energy of the first material (outlined above). An example procedure for measuring the lowest spin doublet excitation energy will now be described. A similar procedure as described above for measurement of the lowest spin singlet excitation energy may be used. The samples are photoexcited with a pulsed laser of higher energy than the absorption onset. The resultant light emission is then recorded by a time-resolved spectrometer, for example an intensified charge-coupled device camera. Any photoluminescence timeslice after 1 ns (after relaxation from ‘hot’ states) can be used to determine the doublet energy, as the D₁ state is the lowest-lying state of any spin multiplicity in the radical materials. A spectrum is produced from the measurement, having wavelength on the x-axis, with emission on the y-axis. From the spectrum, the 0-0 vibronic peak should then be related to D₁.

The absorption extinction coefficient for the lowest energy transition can be determined from UV-visible spectrophotometry of the second material with known concentration in a sample cuvette of known path length. A spectrometer is used to obtain a measurement for absorbance, A, at a given wavelength corresponding to the lowest spin doublet excitation energy. The absorption extinction coefficient for the lowest energy transition ε is then determined from the Beer-Lambert law:

$$ε = \frac{A}{c l}$$

where c is the known sample concentration in molar units, and l is the known pathlength, i.e. the distance that the light travels through the solution, for the cuvette in cm.

The measurements for transient photoluminescence were undertaken using a pulsed 355 nm laser (100 fs pulse width) to photoexcite the samples. An integrated CCD camera was used to record the photoluminescence spectral slices for nanosecond to microsecond timescales. The samples were fabricated by thermal vacuum deposition with effusion sources (chamber pressure<10⁻⁷ Torr, source temperature=100° C.-500° C., total deposition rate<2 Å/s, final thickness=150-300 nm). In order to remove the influence of oxygen on the triplet excited state kinetics, the samples were encapsulated in an oxygen-free glovebox environment.

Current density-voltage-electroluminescence (J-V-EL) characteristics were measured using a Keithley 2400 sourcemeter, Keithley 2000 multimeter and a calibrated silicon photodiode. The external quantum efficiency is the ratio of number of photons emitted in the forward direction to electrons injected into the OLED. For the number of electrons: the current-voltage characteristic is obtained by a Keithley 2400 sourcemeter which records the current in the device for different voltage settings (e.g. from 0 to 12V at 0.1V intervals). For the number of photons emitted: a calibrated Si photodiode is placed at a fixed distance from the OLED. The photodiode is combined with a Keithley 2000 multimeter for which the recorded voltage may be related to number of photons. The emission profile is assumed to be Lambertian.

The normalised electroluminescence (EL) profiles of the devices were obtained using an Andor iStar DH740 CCI-010 electrically-gated intensified charge-coupled device (ICCD) camera with Andor SR303i spectrograph.

For the first material, the HOMO and LUMO values can be obtained by cyclic voltammetry. For this measurement, an electrolyte containing the materials whose HOMO and LUMO energy levels should be determined are contacted with a reference electrode (e.g. Ag/Ag+). A voltage is applied and swept in forward (e.g. negative to positive) and reverse directions (e.g. positive to negative). For positive applied voltages, the first material will be oxidised (i.e. electron removed from HOMO); and for negative applied voltages, the first material will be reduced (i.e. electron into LUMO). The onset of current indicates that there is energy matching between the probe molecules and reference electrode, and the average from forward and reverse sweeps of voltage will be taken for the HOMO and LUMO energies. The same process may be used to measure the HOMO and LUMO values for the third material.

For the second material, the SOMO energy (for reduction, addition of electron) can be determined in the same manner as for the LUMO energy of the first material by cyclic voltammetry. In cyclic voltammetry, positive applied voltages correspond to oxidation of the second material: i.e. oxidation, removal of electron from the second material SOMO. Consequently, the HOMO energy for the second material can be estimated by addition of the radical lowest energy doublet excited state energy to the second material SOMO energy (for reduction). Alternatively, the HOMO energy of the second material can be estimated as the HOMO energy of the isolated donor component (from cyclic voltammetry) in donor-acceptor radicals.

For assessing the electrochemical stability of the second material, repeated cyclic voltammetry measurements are undertaken (e.g. 20 repeated sweeps from positive to negative voltage, and negative to positive voltage) for repeated cycles of oxidation and reduction. Electrochemical stability will result in substantially overlapping cyclic voltammetry profiles for all sweeps (i.e. first, second, third sweep and so on, with no hysteresis).

For assessing the thermal stability of the second material, a thermogravimetric measurement is undertaken by gradually heating a powder sample and noting the temperature (T_{G}) at which 95% of the original sample mass is retained. This is equivalent to 5% of sample decomposition. The thermal decomposition temperature must be higher than the deposition temperature of the second material in OLED fabrication by high vacuum deposition method. For TTM-3NCz, T_{G}=362° C.; TTM-3PCz, T_{G}=367° C.; TTM-αPylD, T_{G}=177° C.; decomposition temperature ˜150° C. for these materials at 0.05 Å/s as used in device fabrication.

For assessing the photo-stability of the second material, a solution sample (100 μM in chloroform) is subjected to continuous wave laser excitation (e.g. 355 nm, a higher energy than second material bandgap) in the absence of oxygen. The steady-state sample photoluminescence is recorded using a spectrometer. An exponential fit is used for the decay lifetime of the recorded photoluminescence. Stable radicals may exhibit time constants of greater than 1 hour. For TTM-3NCz, the time constant is greater than 2.5 hrs. There was no change in photoluminescence intensity over 2.5 hrs.

The formation of the exciplex can be seen from a photoluminescence spectrum as described in Park et al., Adv. Funct. Mater., 2013, 23, 4914-4920, the entire contents of which are incorporated herein by reference, and which shows an example photoluminescence spectrum for a combination of TCTA:B3PYMPM showing the exciplex emission. A sample of the material is prepared as a film including the first and third materials in the same concentrations as included in the device. Light from a laser is applied to the film and a wavelength-dependent photoluminescence spectrum detected by a charge-coupled device. Where an exciplex is formed, the emission spectrum is related to the energy difference between the HOMO of the first material and the LUMO of the third material. A photoluminescence spectra of a thin film of the first material, a thin film of the third material, and a thin film of the combination of the first and third material may also be compared in order to show the presence of the exciplex in the combination of materials. Where an exciplex is formed, there is a new photoluminescence profile which cannot be formed by linear combination of the first and third material photoluminescence profiles.

While certain embodiments have been described, these embodiments have been presented by way of example only, and are not intended to limit the scope of the inventions. Indeed the novel methods and apparatus described herein may be embodied in a variety of other forms; furthermore, various omissions, substitutions and changes in the form of methods and apparatus described herein may be made.

Exemplary embodiments of the invention are provided below.

Embodiment 1. An organic light emitting device, comprising: an anode; a cathode; and an emissive layer between the anode and the cathode, wherein the emissive layer comprises a first material which is an organic semiconductor compound and a second material which is a different organic semiconductor compound that has a spin doublet ground state; and wherein a lowest spin singlet excitation energy of the first material and a lowest spin triplet excitation energy of the first material are greater than a lowest spin doublet excitation energy of the second material.

Embodiment 2. The device according to embodiment 1, configured such that during operation, energy is transferred from the spin singlet excited state in the first material and the spin triplet excited state in the first material to create excited doublet states in the second material, and light is subsequently emitted from the second material.

Embodiment 3. The device according to any preceding embodiment, wherein the second material is a compound that emits fluorescent light when transitioning from a lowest spin doublet excitation energy level to a ground energy level, with a lifetime for 90% of the emission of less than 1 microsecond following photoexcitation.

Embodiment 4. The device according to any preceding embodiment, wherein the absorption extinction coefficient of the second material for the lowest energy transition is greater than 1000 M⁻'cm⁻¹.

Embodiment 5. The device according to any preceding embodiment, wherein a difference between the lowest spin singlet excitation energy level of the first material and the lowest spin doublet excitation energy of the second material is less than 1.5 eV.

Embodiment 6. The device according to any preceding embodiment, wherein the difference between the lowest spin singlet excitation energy level of the first material and the lowest spin triplet excitation energy level of the first material is less than 0.2 eV.

Embodiment 7. The device according to any preceding embodiment, wherein an amount of the first organic semiconductor compound in the emissive layer is greater than an amount of the second organic semiconductor compound in the emissive layer.

Embodiment 8. The device according to any preceding embodiment, wherein the emissive layer comprises a third material which is an organic semiconductor compound, wherein a lowest spin singlet excitation energy level of the third material is greater than the lowest spin singlet excitation energy of the first material.

Embodiment 9. The device according to any preceding embodiment, wherein the emissive layer comprises a third material, and wherein the third material is doped with the second material with a concentration of less than or equal to 10% by weight and doped with the first material with a concentration of greater than or equal to 2% by weight.

Embodiment 10. The device according to any preceding embodiment, wherein the emissive layer comprises a third material which is an organic semiconductor compound, and wherein the third material is doped with the second material with a concentration of less than or equal to 5% by weight and doped with the first material with a concentration of greater than or equal to 5% by weight.

Embodiment 11. The device according any preceding embodiment, wherein the difference between the LUMO energy level of the first material and the SOMO energy level of the second material is less than 0.7 eV.

Embodiment 12. The device according to any preceding embodiment, wherein the first material is a thermally-activated delayed fluorescent (TADF) material.

Embodiment 13. The device according to any preceding embodiment, wherein the first material is a compound having an electron deficient component and an electron rich component.

Embodiment 14. The device according to any preceding embodiment, wherein the first material is one or more selected from the group consisting of:

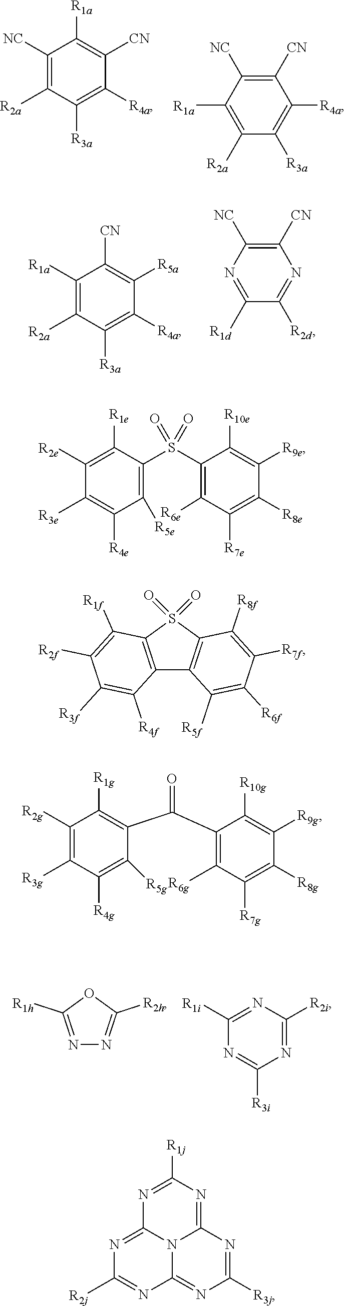

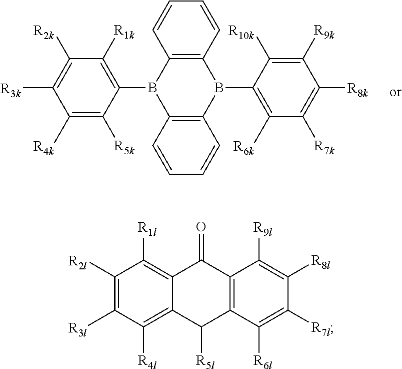

wherein R₁ₐ, R₂ₐ, R₃ₐ, R₄ₐ, R₅ₐ, R_{1d}, R_{2d}, R₁ₑ, R₂ₑ, R₃ₑ, R₄ₑ, R₅ₑ, R₆ₑ, R₇ₑ, R₈ₑ, R₉ₑ, R₁₀ₑ, R_{1f}, R_{2f}, R_{3f}, R_{4f}, R_{5f}, R_{6f}, R_{7f}, R_{8f}, R_{1g}, R_{2g}, R_{3g}, R_{4g}, R_{5g}, R_{6g}, R_{7g}, R_{8g}, R_{9g}, R_{10g}, R₁ₕ, R₂ₕ, R₁ᵢ, R₂ᵢ, R₃ᵢ, R₁ⱼ, R₂ⱼ, R₃ⱼ, R₁ₖ, R₂ₖ, R₃ₖ, R₄ₖ, R₅ₖ, R₆ₖ, R₇ₖ, R₈ₖ, R₉ₖ, R₁₀ₖ, R₁ₗ, R₂ₗ, R₃ₗ, R₄ₗ, R₅ₗ, R₆ₗ, R₇ₗ, R₈ₗ, R₉ₗ are independently selected from the groups consisting of H,

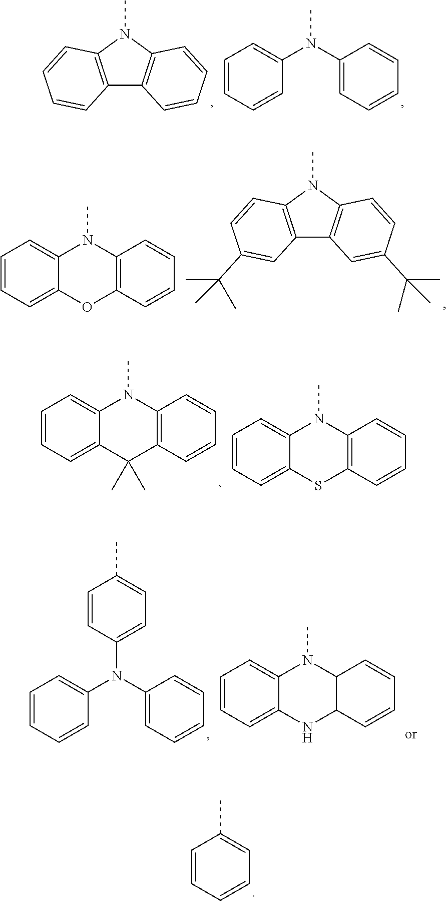

Embodiment 15. The device according to any preceding embodiment, wherein the first material is one or more selected from the group consisting of: 10-(4-(4-(10H-Phenoxazin-10-yl)phenylsulfonyl)phenyl)-10H-phenoxazine (PXZ-DPS), 5,10-bis(4-(9H-carbazol-9-yl)-2,6-dimethylphenyl)-5,10-dihydroboranthrene (CzDBA) and 2,4,5,6-tetra(9H-carbazol-9-yl)isophthalonitrile (4CzIPN).

Embodiment 16. The device according to any preceding embodiment, wherein the second material is a stable organic radical.

Embodiment 17. The device according to any preceding embodiment, wherein the second material comprises a donor moiety and an acceptor moiety.

Embodiment 18. The device according to embodiment 17, wherein the acceptor moiety is selected from the group consisting of:

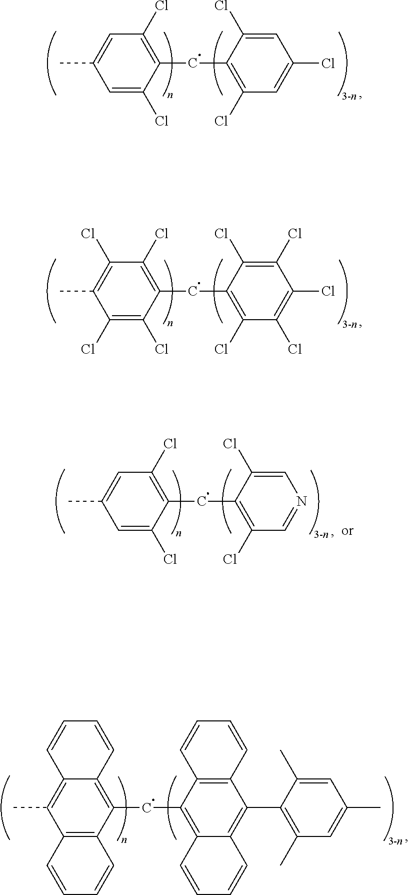

wherein n=1, 2 or 3 and _ _ _ _ _ _ indicates the point attachment to the donor moiety.

Embodiment 19. The device according to embodiment 17 or embodiment 18, wherein the donor moiety is selected from the group consisting of: _ _ _ _ _ _ H, _ _ _ _ _ _ Cl,

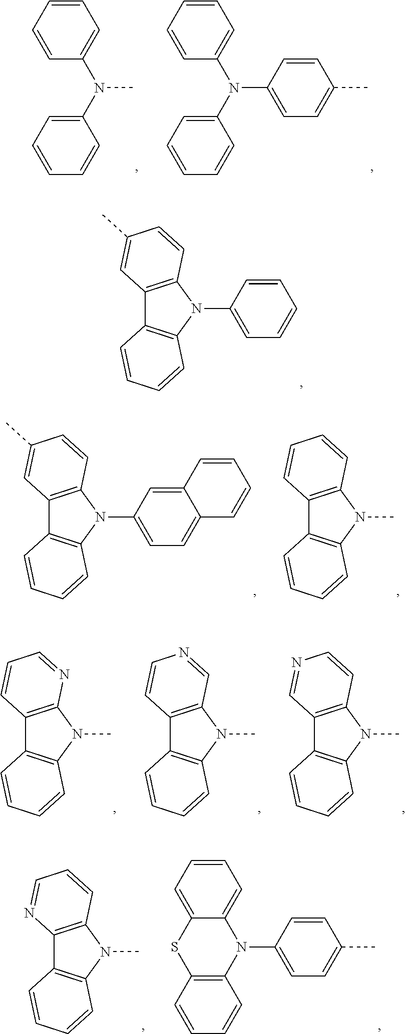

wherein _ _ _ _ _ _ indicates the point of attachment to the acceptor moiety.

Embodiment 20. The device according to any preceding embodiment, wherein the acceptor moiety is a TTM radical.

Embodiment 21. The device according to any preceding embodiment, wherein the second material is one or more selected from the group consisting of:

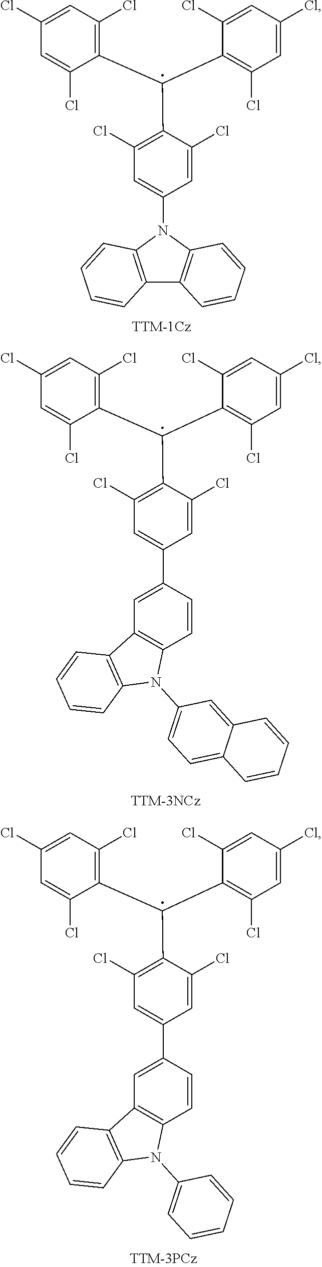

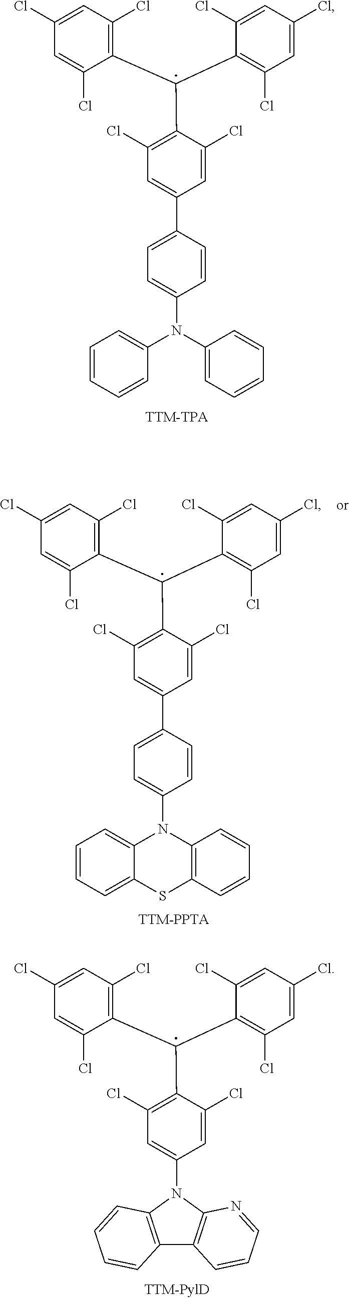

Embodiment 22. A method of fabricating an organic light emitting device, comprising:

forming an emissive layer between an anode and a cathode, wherein the emissive layer comprises a first material which is an organic semiconductor compound and a second material which is a different organic semiconductor compound that has a spin doublet ground state; and wherein a lowest spin singlet excitation energy of the first material and a lowest spin triplet excitation energy of the first material are greater than a lowest spin doublet excitation energy of the second material.

Embodiment 23. A method of operating an organic light emitting device comprising an anode, a cathode, and an emissive layer between the anode and the cathode, wherein the emissive layer comprises a first material which is an organic semiconductor compound and a second material which is a different organic semiconductor compound that has a spin doublet ground state, the method comprising: applying a voltage across the device, such that spin singlet excited states and spin triplet excited states are formed for the first material, wherein energy is transferred from spin singlet excited states in the first material and spin triplet excited states in the first material to form spin doublet excited states in the second material, wherein the second material emits fluorescent light when transitioning from a spin doublet excited state to a ground state.

1. An organic light emitting device, comprising:
an anode;
a cathode; and
an emissive layer between the anode and the cathode, wherein the emissive layer comprises a first material which is an organic semiconductor compound and a second material which is a different organic semiconductor compound that has a spin doublet ground state; and
wherein a lowest spin singlet excitation energy of the first material and a lowest spin triplet excitation energy of the first material are greater than a lowest spin doublet excitation energy of the second material.

2. The device according to claim 1, configured such that during operation, energy is transferred from the spin singlet excited state in the first material and the spin triplet excited state in the first material to create excited doublet states in the second material, and light is subsequently emitted from the second material.

3. (canceled)

4. The device according to claim 1, wherein the first material is a thermally-activated delayed fluorescent (TADF) material.

5. (canceled)

6. (canceled)

7. (canceled)

8. The device according to claim 1, wherein the first material is one or more selected from the group consisting of: 10-(4-(4-(10H-Phenoxazin-10-yl)phenylsulfonyl)phenyl)-10H-phenoxazine (PXZ-DPS), 5,10-bis(4-(9H-carbazol-9-yl)-2,6-dimethylphenyl)-5,10-dihydroboranthrene (CzDBA) and 2,4,5,6-tetra(9H-carbazol-9-yl)isophthalonitrile (4CzIPN).

9. The device according to claim 1, wherein the emissive layer comprises a third material which is an organic semiconductor compound, wherein a lowest spin singlet excitation energy level of the third material is greater than the lowest spin singlet excitation energy of the first material.

10. The device according to claim 1, wherein the emissive layer comprises a third material, and wherein the third material is doped with the second material with a concentration of less than or equal to 10% by weight and doped with the first material with a concentration of greater than or equal to 2% by weight.

11. (canceled)

12. A device according to claim 1, wherein the emissive layer comprises an exciplex host which is a combination of the first material and a third material that combine together to form an exciplex having a lowest spin singlet excitation energy and a lowest spin triplet excitation energy that are greater than a lowest spin doublet excitation energy of the second material.

13. The device according to claim 12, configured such that during operation, energy is transferred from the spin singlet excited state in the exciplex and the spin triplet excited state in the exciplex to the second material, and light is subsequently emitted from the second material.

14. The device according to claim 12, wherein the lowest spin singlet excitation energy and the lowest spin triplet excitation energy of the first material are higher than the lowest spin singlet excitation energy and the lowest spin triplet excitation energy of the exciplex.

15. (canceled)

16. (canceled)

17. (canceled)

18. (canceled)

19. (canceled)

20. The device according to claim 12, wherein the first material is 4,4-bis(carbazol-9-yl)biphenyl (CBP), 3-bis(9-carbazolyl)benzene (mCP), N,N′-di(1-naphthyl)-N,N′-diphenyl-(1,1′-biphenyl)-4,4′-diamine (NPB), tris(4-carbazoyl-9-ylphenyl)amine (TCTA), 9,9′-Diphenyl-9H, 9′H-3,3′-bicarbazole (BCzPh), 1,1-Bis[(di-4-tolylamino)phenyl]cyclohexane (TAPC), 9-Phenyl-3,6-bis(9-phenyl-9Hcarbazol-3-yl)-9H-carbazole (Tris-PCz), 1,3-Bis(N-carbazolyl)benzene (mCP) or N,N′-Di(1-naphthyl)-N,N′-diphenyl-(1,1′-biphenyl)-4,4′-diamine (NBP), 4,4′,4″-tris[phenyl(m-tolyl)amino]triphenylamine (m-MTDATA), or N,N′-bis(3-methylphenyl)-N,N′-diphenyibenzidine (TPD).

21. (canceled)

22. (canceled)

23. (canceled)

24. The device according to claim 9, wherein the energy of the lowest unoccupied molecular orbital of the first material is higher than the energy of the lowest unoccupied molecular orbital of the third material, and the energy of the highest occupied molecular orbital of the first material is higher than the energy of the highest occupied molecular orbital of the material.

25. (canceled)

26. (canceled)

27. The device according to claim 9, wherein the lowest unoccupied molecular orbital energy level of the third material is higher than the singly occupied molecular orbital energy level of the second material for reduction.

28. (canceled)

29. (canceled)

30. (canceled)

31. The device according to claim 9, wherein the third material is bis-4,6-(3,5-di-4-pyridylphenyl)-2-methylpyrimi-dine (B4PYMPM), bis-4,6-(3,5-di(pyridin-4-yl)phenyl)-2-phenylpyrimidine (B4PYPPM), tris(2,4,6-trimethyl-3-(pyridin-3-yl)phenyl)borane (3TPYMB), 1,3-bis[3,5-di(pyridin-3-yl)phenyl]benzene (BmPyPhB), 3,3′[5′[3-(3-pyridinyl)phenyl][1,1′:3′,1″-terphenyl]-3,3′-diyl]bispyridine (TmPyPB), bis-9,9′-spirobi[fluoren-2-yl]-methanone (BSFM), 4,6-Bis(3,5-di(pyridin-3-yl)phenyl)-2-methylpyrimidine (B3PymPm) or 2,2′,2″-(1,3,5-benzinetriyl)-tris(1-phenyl-1-H-benzimidazole) (TPBi).

32. (canceled)

33. (canceled)

34. (canceled)

35. (canceled)

36. The device according to claim 1, wherein the second material is a compound that emits fluorescent light when transitioning from a lowest spin doublet excitation energy level to a ground energy level, with a lifetime for 90% of the emission of less than 1 microsecond following photoexcitation.

37. (canceled)

38. (canceled)

39. The device according to claim 1, wherein the second material is a stable organic radical.

40. The device according to claim 1, wherein an amount of the first material in the emissive layer is greater than an amount of the second material in the emissive layer.

41. (canceled)

42. The device according to claim 1, wherein the second material comprises a donor moiety and an acceptor moiety, wherein the acceptor moiety is selected from the group consisting of: 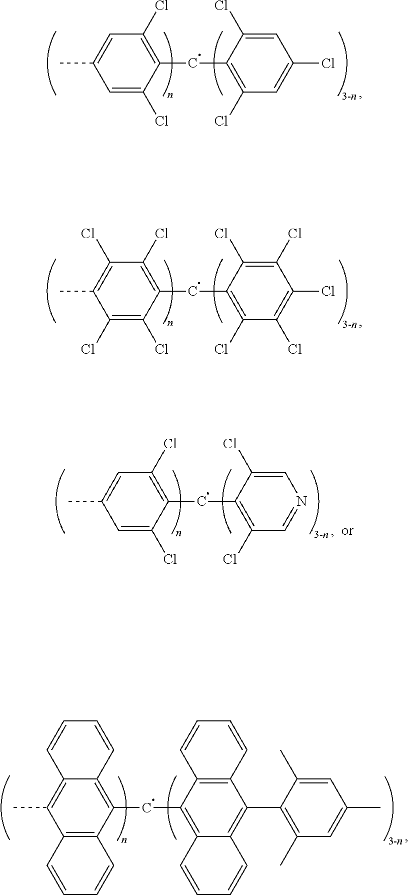
wherein n=1, 2 or 3 and _ _ _ _ _ _ indicates the point attachment to the donor moiety and the donor moiety is selected from the group consisting of: _ _ _ _ _ _ H, _ _ _ _ _ _ Cl, 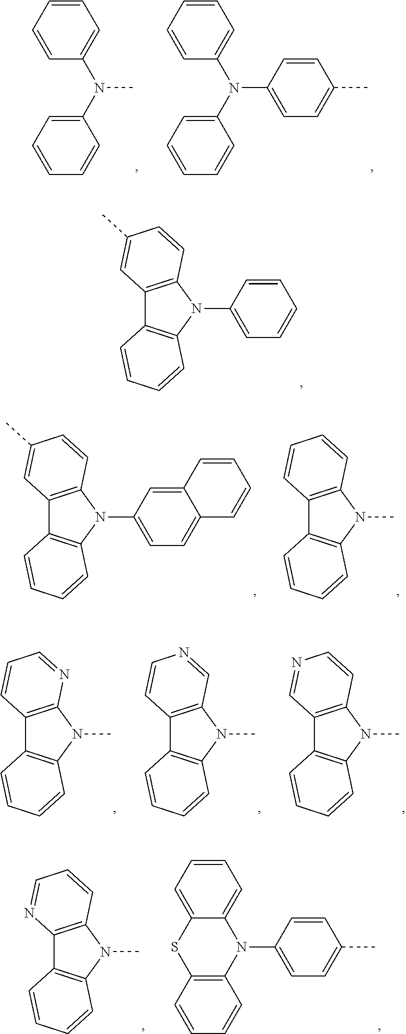
wherein _ _ _ _ _ _ indicates the point of attachment to the acceptor moiety.

43. (canceled)

44. (canceled)

45. (canceled)

46. The device according to claim 1, wherein the second material is one or more selected from the group consisting of:

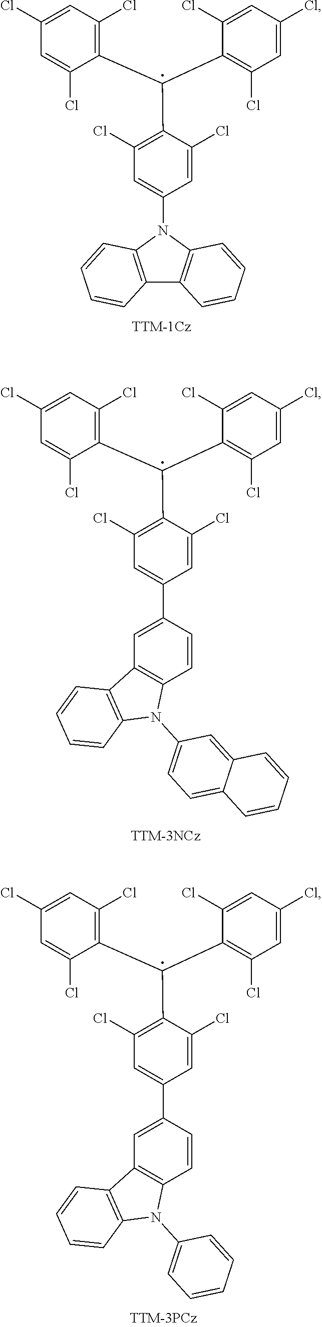

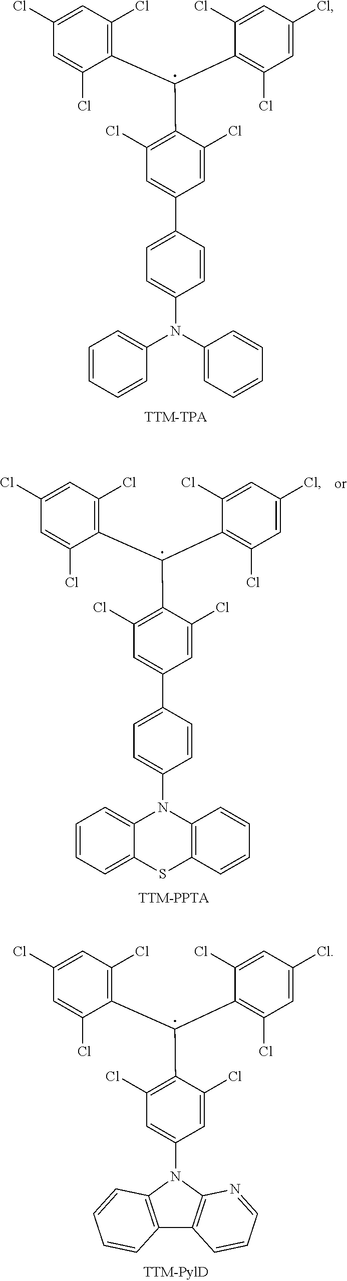

47. A method of fabricating an organic light emitting device, comprising:
forming an emissive layer between an anode and a cathode, wherein the emissive layer comprises a first material which is an organic semiconductor compound and a second material which is a different organic semiconductor compound that has a spin doublet ground state; and
wherein a lowest spin singlet excitation energy of the first material and a lowest spin triplet excitation energy of the first material are greater than a lowest spin doublet excitation energy of the second material.

48. A method of operating an organic light emitting device comprising an anode, a cathode, and an emissive layer between the anode and the cathode, wherein the emissive layer comprises a first material which is an organic semiconductor compound and a second material which is a different organic semiconductor compound that has a spin doublet ground state, the method comprising:
applying a voltage across the device, such that spin singlet excited states and spin triplet excited states are formed for the first material, wherein energy is transferred from spin singlet excited states in the first material and spin triplet excited states in the first material to form spin doublet excited states in the second material, wherein the second material emits fluorescent light when transitioning from a spin doublet excited state to a ground state.
